(19) United States
(12) Patent Application Publication
(10) Pub. No.: US 2026/0161857 A1
(43) Pub. Date: Jun. 11, 2026

(54) METHOD AND SYSTEM FOR DETERMINING PREDICTED RESERVOIR SIMULATION SOLUTIONS USING ARTIFICIAL INTELLIGENCE

(71) Applicant: SAUDI ARABIAN OIL COMPANY, Dhahran (SA)

(72) Inventors: Egor Illarionov, Moscow (RU); Musheg Petrosyants, Moscow (RU); Dmitry Koroteev, Moscow (RU); Ekaterina Tolstaya, Moscow (RU); Abdulrahman Manea, Dhahran (SA)

(73) Assignee: SAUDI ARABIAN OIL COMPANY, Dhahran (SA)

(21) Appl. No.: 18/708,765

(22) PCT Filed: Jul. 24, 2023
(86) PCT No.: PCT/RU2023/000224

§ 371 Date: May 9, 2024

(51) Int. Cl. G06F 30/28; G06F 30/27

(52) U.S. Cl. CPC G06F 30/28; G06F 30/27

(57) ABSTRACT

A method may include determining various adaptive weights using a machine-learning model, first simulation data, and second simulation data. The method may further include determining predicted simulation data for a time step of the reservoir simulation using the adaptive weights, the first simulation data, the second simulation data, grid model data, and various reservoir simulation parameters. The method may further include determining whether the predicted simulation data satisfies a predetermined criterion. The method may further include determining, in response to determining that the predicted simulation data fails to satisfy the predetermined criterion, updated simulation data for the time step of the reservoir simulation based on the predicted simulation data, the grid model data, the reservoir simulation parameters, a search method, and the reservoir equations.

### BACKGROUND

An important issue in reservoir modeling is the amount of computation time required to perform a particular reservoir simulation. To reduce computation time, some simulation methods reduce the total number of time steps used to perform the simulation as well as the length of each time step. However, as the distance between time steps increases, the precise reservoir solution for a particular time step becomes more computationally intensive to determine by a computer system. Where the initial solution at a new time point differs significantly from the actual solution of the given time point, many costly iterations may be required to determine an accurate final solution at the given time step.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments relate to a method that includes obtaining grid model data regarding a geological region of interest. The grid model data includes porosity data, lithological data, and permeability data. The method further includes obtaining various reservoir simulation parameters for a reservoir simulation of the geological region of interest. The reservoir simulation parameters include well data regarding one or more wells in the geological region of interest. The method further includes obtaining various reservoir equations for the reservoir simulation. The method further includes determining, by a computer processor, first simulation data for a first time step of the reservoir simulation based on the grid model data, the reservoir simulation parameters, and the reservoir equations. The method further includes determining, by the computer processor, second simulation data for a second time step of the reservoir simulation based on the grid model data, the reservoir simulation parameters, and the reservoir equations. The method further includes determining, by the computer processor, various adaptive weights using a machine-learning model, the first simulation data, and the second simulation data. The method further includes determining, by the computer processor, predicted simulation data for a third time step of the reservoir simulation using the adaptive weights, the first simulation data, the second simulation data, the grid model data, and the reservoir simulation parameters. A respective adaptive weight among the adaptive weights adjusts a contribution of respective simulation data for determining the predicted simulation data. The method further includes determining, by the computer processor, whether the predicted simulation data satisfies a predetermined criterion. The predetermined criterion is a convergence criterion corresponding to a reservoir solution to the reservoir equations converging to a predetermined limit. The method further includes determining, by the computer processor and in response to determining that the predicted simulation data fails to satisfy the predetermined criterion, updated simulation data for the third time step of the reservoir simulation based on the predicted simulation data, the grid model data, the reservoir simulation parameters, a search method, and the reservoir equations.

In general, in one aspect, embodiments relate to a system that includes various wells in a geological region of interest and various control systems coupled to the wells. The system further includes a reservoir simulator that includes a computer processor. The reservoir simulator is coupled to the control systems. The reservoir simulator being configured to perform a method. The reservoir simulator obtains grid model data regarding a geological region of interest. The grid model data includes porosity data, lithological data, and permeability data. The reservoir simulator obtains various reservoir simulation parameters for a reservoir simulation of the geological region of interest. The reservoir simulation parameters include well data regarding the wells. The reservoir simulator obtains various reservoir equations for the reservoir simulation. The reservoir simulator determines first simulation data for a first time step of the reservoir simulation based on the grid model data, the reservoir simulation parameters, and the reservoir equations. The reservoir simulator determines second simulation data for a second time step of the reservoir simulation based on the grid model data, the reservoir simulation parameters, and the reservoir equations. The reservoir simulator determines various adaptive weights using a machine-learning model, the first simulation data, and the second simulation data. The reservoir simulator determines predicted simulation data for a third time step of the reservoir simulation using the adaptive weights, the first simulation data, the second simulation data, the grid model data, and the reservoir simulation parameters. A respective adaptive weight among the adaptive weights adjusts a contribution of respective simulation data for determining the predicted simulation data. The reservoir simulator determines whether the first predicted simulation data satisfies a predetermined criterion. The predetermined criterion is a convergence criterion corresponding to a reservoir solution to the reservoir equations converging to a predetermined limit. The reservoir simulator determines, in response to determining that the predicted simulation data fails to satisfy the predetermined criterion, updated simulation data for the third time step of the reservoir simulation based on the predicted simulation data, the grid model data, the reservoir simulation parameters, a search method, and the reservoir equations.

In some embodiments, a machine-learning selection model is obtained that includes a machine-learning model that is different from a machine-learning model for predicting simulation data. Simulation data may be determined for various time steps in a reservoir simulation. A predicted time step size may be determined for various future time steps in the reservoir simulation using the machine-learning selection model and the simulation data. Simulation data may be determined for the future time steps using the predicted time step size, grid model data, and various reservoir simulation parameters.

In some embodiments, an agent policy is determined for a reservoir simulation based on a geological region of interest. The agent policy may determine a first set of adaptive weights. The agent policy may be updated to produce an updated agent policy using a reinforcement learning algorithm and simulation data for a time step. A second set of adaptive weights may be determined based on the updated agent policy. Predicted simulation data may be determined for the time step using the second set of adaptive weights. In some embodiments, a training dataset is obtained based on various reservoir simulations for various geological regions. The training dataset may include input simulation data for one or more time steps in a respective reservoir simulation and output simulation data for a predetermined time step for prediction in the respective reservoir simulation. An initial model may be trained to produce a machine-learning model for predicting simulation data using the training dataset and various machine-learning epochs. In some embodiments, a machine-learning model is a fully-connected neural network that obtains grid model data and simulation data for a time step as input features to an input layer. The fully-connected neural network may output various adaptive weights.

In some embodiments, a search method is a Newton-Raphson method. Various reservoir equations may include one or more Darcy's equations, one or more flow equations, one or more material-balance equations, and one or more constraint rate equations, and one or more black-oil equations. Updated simulation data may be determined using a nonlinear solver that determines a reservoir solution to various reservoir equations based on the Newton-Raphson method. In some embodiments, various reservoir simulation parameters includes various well parameters for one or more production wells and various well parameters for one or more injection wells. A first set of well parameters may include a predetermined rate of well production during the reservoir simulation. A second set of well parameters describe one or more stimulation operations for the one or more injection wells. In some embodiments, predicted simulation data is based on a linear combination of first simulation data and second simulation data using a regression function and various adaptive weights.

In some embodiments, a time selection is obtained for a reservoir simulation. The time selection may include a starting time, an ending time, and a predetermined time interval or step size for various time steps in the reservoir simulation. The reservoir simulation may be an iterative process that includes a first time step, a second time step, and a third time step. In some embodiments, various well logs are obtained, using a logging system, from a well in a geological region of interest. Grid model data may be determined from the well logs. In some embodiments, various core samples are obtained, using a coring system, from a well in a geological region of interest. Grid model data may be determined from the core samples.

In light of the structure and functions described above, embodiments of the invention may include respective means adapted to carry out various steps and functions defined above in accordance with one or more aspects and any one of the embodiments of one or more aspect described herein.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIGS. 1, 2, 3A, and 3B show systems in accordance with one or more embodiments.

FIG. 4 shows a flowchart in accordance with one or more embodiments.

FIGS. 5A, 5B, 5C, 5D, 6A, 6B, 7A, and 7B show examples in accordance with one or more embodiments.

FIG. 8 shows a computer system in accordance with one or more embodiments.

FIG. 9 shows an example in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

In general, embodiments of the disclosure include systems and methods for performing reservoir simulations using adaptive weights and machine learning. In some embodiments, for example, various reservoir simulation tasks are performed faster by providing more accurate initial simulation data prior to performing iterations with a nonlinear solver. In particular, initial simulation data may be predicted for a reservoir solution based on adaptive weights that are produced using a machine learning architecture. The reservoir solution may correspond to a simulated solution for a system of partial differential equations describing a multiphase flow in a porous medium (i.e., in a geological region of interest). The predicted simulation data may result in fewer iterations of a nonlinear solver for determining a precise reservoir solution at a particular time step. The predicted simulation data may be based on previous simulation data from multiple past time steps and adaptive weights that emphasize different simulation datasets according to the adaptive weights. More specifically, adaptive weights may identify portions of one or more previous reservoir solutions that should be updated in order to approximate the reservoir solution at a current time step. Afterwards, this predicted simulation data based on these identified portions may undergoing an iterative process for finding an accurate reservoir solution. In some embodiments, an artificial neural network is used to predict the adaptive weights, such as a fully-connected neural network.

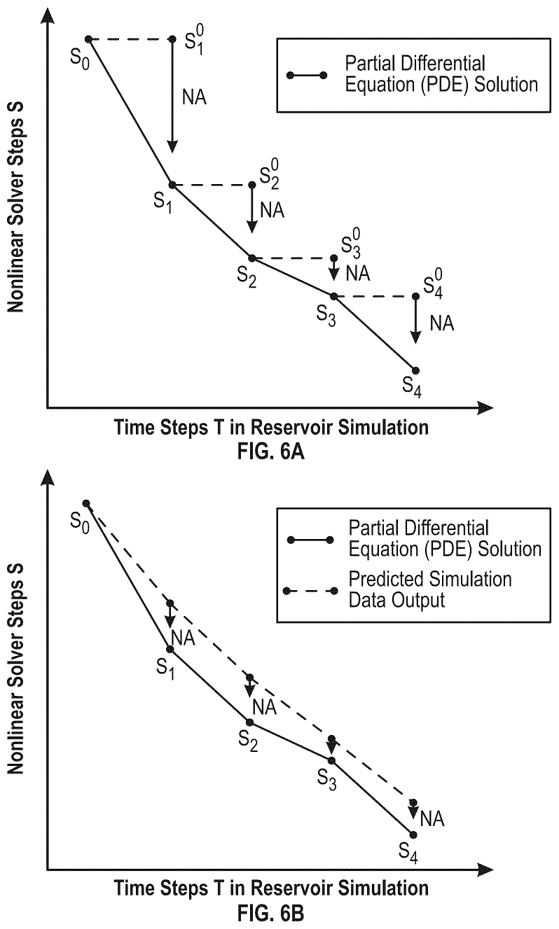

Furthermore, some machine-learning models provide a significant advantage in faster computations using already computed reservoir solutions for training and predicting a close approximation of the precise solution. In particular, FIGS. 6A and 6B shows the advantages of using a machine-learning approach to determine reservoir simulation data in comparison to a conventional approach. In the conventional approach, simulation data is initialized for a nonlinear solver using the previous time step's output as the initial values. These initial values may be updated iteratively to determine a final solution to one or more partial differential equations (PDEs) at a particular time step. In FIG. 6A, a conventional initialization of a nonlinear solver is shown with corresponding reservoir solutions for various reservoir equations. Likewise, FIG. 6B shows an alternate initialization on a nonlinear solver is shown based on predicted simulation data using a trained machine-learning model. Here, the trained machine-learning model may predict initial simulation data without using adaptive weights, for example. Accordingly, FIG. 6B allows initial simulation data that is closer to the final reservoir solution.

Furthermore, conventional simulation techniques may include explicit, semi-implicit, and/or fully-implicit schemes to solving various reservoir equations. In comparison to an explicit scheme, implicit schemes may be based on solving a system of linear equations where various derivatives are determined at the next time step. On the other hand, semi-implicit schemes are a combination of techniques, such that some reservoir solutions are determine with the implicit scheme, and some reservoir solutions are determined with the explicit one.

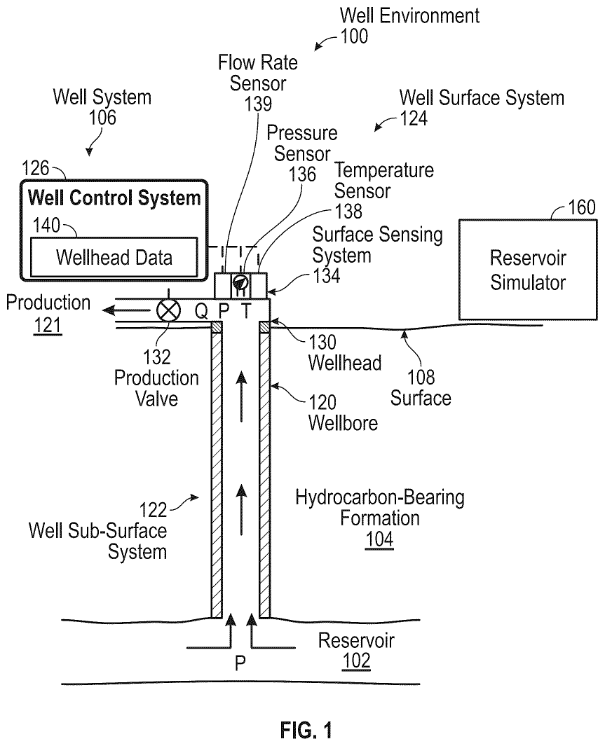

Turning to FIG. 1, FIG. 1 shows a schematic diagram in accordance with one or more embodiments. As shown in FIG. 1, FIG. 1 illustrates a well environment (100) that includes a hydrocarbon reservoir (“reservoir”) (102) located in a subsurface hydrocarbon-bearing formation (104) and a well system (106). The hydrocarbon-bearing formation (104) may include a porous or fractured rock formation that resides underground, beneath the earth's surface (“surface”) (108). In the case of the well system (106) being a hydrocarbon well, the reservoir (102) may include a portion of the hydrocarbon-bearing formation (104). The hydrocarbon-bearing formation (104) and the reservoir (102) may include different layers of rock having varying properties, such as varying degrees of permeability, porosity, and resistivity. In the case of the well system (106) being operated as a production well, the well system (106) may facilitate the extraction of hydrocarbons (or “production”) from the reservoir (102).

In some embodiments, the well system (106) includes a wellbore (120), a well sub-surface system (122), a well surface system (124), and a well control system (126). The control system (126) may control various operations of the well system (106), such as well production operations, well completion operations, well maintenance operations, and reservoir monitoring, assessment and development operations. Control systems may include a programmable logic controller (PLC), a distributed control system (DCS), a supervisory control and data acquisition (SCADA), and/or a remote terminal unit (RTU). For example, a programmable logic controller may control valve states, fluid levels, pipe pressures, warning alarms, and/or pressure releases throughout a well facility or power-generation facility. In particular, a programmable logic controller may be a ruggedized computer system with functionality to withstand vibrations, extreme temperatures, wet conditions, and/or dusty conditions, for example, around a production well. A distributed control system may be a computer system for managing various processes at various facilities using multiple control loops. As such, a distributed control system may include various autonomous controllers (such as remote terminal units) positioned at different locations throughout the facility to manage operations and monitor processes. Likewise, a distributed control system may include no single centralized computer for managing control loops and other operations. On the other hand, a SCADA system may include a control system that includes functionality for enabling monitoring and issuing of process commands through local control at a facility as well as remote control outside the facility. With respect to an RTU, an RTU may include hardware and/or software, such as a microprocessor, that connects sensors and/or actuators using network connections to perform various processes in the automation system. Likewise, a control system may be coupled to one or more well devices.

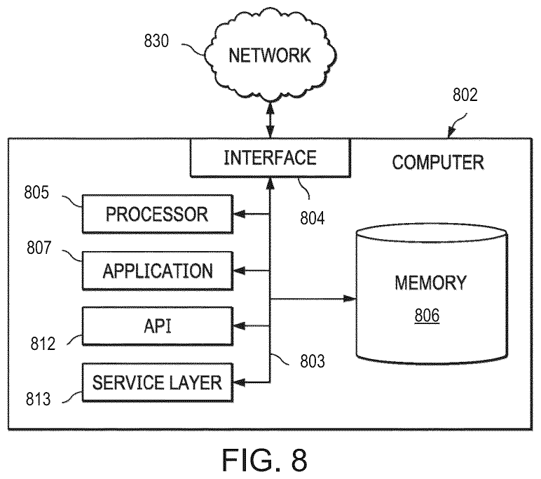

In some embodiments, a well control system includes functionality for transmitting commands to another control system to implement a particular production operation or stimulation operation. For example, a well control system coupled to a reservoir simulator may transmit a network message over a machine-to-machine protocol to a control system based on predicted flow rate data. A command may be transmitted based on a user input or automatically based on changes in production conditions, e.g., after analyzing new reservoir data, electric-power data, and carbon emission data. In some embodiments, the control system (126) includes a computer system that is the same as or similar to that of computer system (802) described below in FIG. 8 and the accompanying description.

The wellbore (120) may include a bored hole that extends from the surface (108) into a target zone of the hydrocarbon-bearing formation (104), such as the reservoir (102). An upper end of the wellbore (120), terminating at or near the surface (108), may be referred to as the “uphole” end of the wellbore (120), and a lower end of the wellbore, terminating in the hydrocarbon-bearing formation (104), may be referred to as the “downhole” end of the wellbore (120). The wellbore (120) may facilitate the circulation of drilling fluids during drilling operations, the flow of hydrocarbon production (“production”) (121) (e.g., oil and gas) from the reservoir (102) to the surface (108) during production operations, the injection of substances (e.g., water) into the hydrocarbon-bearing formation (104) or the reservoir (102) during injection operations, or the communication of monitoring devices (e.g., logging tools) into the hydrocarbon-bearing formation (104) or the reservoir (102) during monitoring operations (e.g., during in situ logging operations).

In some embodiments, during operation of the well system (106), the control system (126) collects and records wellhead data (140) for the well system (106). The wellhead data (140) may include, for example, a record of measurements of wellhead pressure (P) (e.g., including flowing wellhead pressure), wellhead temperature (T) (e.g., including flowing wellhead temperature), wellhead production rate (Q) over some or all of the life of the well system (106), and water cut data. In some embodiments, the measurements are recorded in real-time, and are available for review or use within seconds, minutes or hours of the condition being sensed (e.g., the measurements are available within 1 hour of the condition being sensed). In such an embodiment, the wellhead data (140) may be referred to as “real-time” wellhead data (140). Real-time wellhead data (140) may enable an operator of the well system (106) to assess a relatively current state of the well system (106) and make real-time decisions regarding development of the well system (106) and the reservoir (102), such as on-demand adjustments in regulation of production flow from the well.

In some embodiments, the well surface system (124) includes a wellhead (130). The wellhead (130) may include a rigid structure installed at the “uphole” end of the wellbore (120), at or near where the wellbore (120) terminates at the Earth's surface (108). The wellhead (130) may include structures for supporting (or “hanging”) casing and production tubing extending into the wellbore (120). Production (121) may flow through the wellhead (130), after exiting the wellbore (120) and the well sub-surface system (122), including, for example, the casing and the production tubing. In some embodiments, the well surface system (124) includes flow regulating devices that are operable to control the flow of substances into and out of the wellbore (120). For example, the well surface system (124) may include one or more production valves (132) that are operable to control the flow of production (121). For example, a production valve (132) may be fully opened to enable unrestricted flow of production (121) from the wellbore (120), the production valve (132) may be partially opened to partially restrict (or “throttle”) the flow of production (121) from the wellbore (120), and production valve (132) may be fully closed to fully restrict (or “block”) the flow of production (121) from the wellbore (120), and through the well surface system (124).

Keeping with FIG. 1, in some embodiments, the well surface system (124) includes a surface sensing system (134). The surface sensing system (134) may include sensors for sensing characteristics of substances, including production (121), passing through or otherwise located in the well surface system (124). The characteristics may include, for example, pressure, temperature and flow rate of production (121) flowing through the wellhead (130), or other conduits of the well surface system (124), after exiting the wellbore (120).

In some embodiments, the surface sensing system (134) includes a surface pressure sensor (136) operable to sense the pressure of production (121) flowing through the well surface system (124), after it exits the wellbore (120). The surface pressure sensor (136) may include, for example, a wellhead pressure sensor that senses a pressure of production (121) flowing through or otherwise located in the wellhead (130). In some embodiments, the surface sensing system (134) includes a surface temperature sensor (138) operable to sense the temperature of production (121) flowing through the well surface system (124), after it exits the wellbore (120). The surface temperature sensor (138) may include, for example, a wellhead temperature sensor that senses a temperature of production (121) flowing through or otherwise located in the wellhead (130), referred to as “wellhead temperature” (T). In some embodiments, the surface sensing system (134) includes a flow rate sensor (139) operable to sense the flow rate of production (121) flowing through the well surface system (124), after it exits the wellbore (120). The flow rate sensor (139) may include hardware that senses a flow rate of production (121) (Q) passing through the wellhead (130).

In some embodiments, the well system (106) includes a reservoir simulator (160). For example, the reservoir simulator (160) may include hardware and/or software with functionality for generating one or more reservoir models regarding the hydrocarbon-bearing formation (104) and/or performing one or more reservoir simulations. For example, the reservoir simulator (160) may store well logs (e.g., well logs (240)), one or more grid models (e.g., grid model data (255)) seismic data, and core sample data (e.g., core sample data (245)) regarding core samples for performing simulations. A reservoir simulator may further analyze the well log data, the core sample data, seismic data, and/or other types of data to generate and/or update the one or more reservoir models. More specifically, a reservoir simulation may perform one or more reservoir simulations, where a reservoir simulation may include iteratively generation simulation data (e.g., simulation data (280)) at one or more time steps in a particular simulation. Moreover, a reservoir simulator may perform various types of simulations, such as history matching, predicting production rates at one or more wells, and/or determining the presence of hydrocarbon-producing formations for new wells. Likewise, various reservoir simulation applications may be performed, such as rankings, uncertainty analyses, sensitivity analyses, and/or well-by-well history matching. With respect to history matching, the objective may be to fit measured historical data to a reservoir model. In some embodiments, one or more reservoir simulations may optimize production for a well or group of wells, provide well design parameters for one or more wells, completion operations for one or more wells (e.g., using which down-hole devices), and/or determine stimulation parameters for a reservoir region. While the reservoir simulator (160) is shown at a well site, embodiments are contemplated where reservoir simulators are located away from well sites. In some embodiments, the reservoir simulator (160) may include a computer system that is similar to the computer system (802) described below with regard to FIG. 8 and the accompanying description.

In some embodiments, downhole pressure sensors include absolute pressure transmitters, differential-pressure transmitters, and/or multivariable transmitters. Absolute pressure transmitters may include sensors that measure pressure with respect to a full vacuum, while differential-pressure transmitters may include sensors that are used in flow applications. Multivariable transmitters may measure pressure in addition to other variables, such as temperature. For example, a multivariable transmitter may be a gauge sensor that measures both pressure and temperature at a single point, such as a single quartz crystal. Multivariable transmitters may be transmit-only devices in a well providing pressure and temperature (PT) measurements at fixed time intervals, e.g., using one or more electric lines and one or more hydraulic lines. Likewise, multivariable transmitters may transmit pressure and temperature data to a well surface using a high-speed digital telemetry link. Similar to downhole pressure sensors, downhole temperature sensors may include downhole temperature gauges, temperature transmitters, and/or multivariable transmitters. In some embodiments, permanent downhole gauges (PDGs) are used that are permanently installed in a well and used to detect pressure data and/or temperature data.

In some embodiments, a flow rate sensor is a multiphase flow meter. For example, a multiphase flow meter may include hardware and/or software for determining individual flow rates of different components within a three-phase flow. More specifically, a multiphase flow meter may determine a mass flow rate of a gas component and a mass flow rate of a liquid component (e.g., a component of the three-phase flow that includes oil and water) of the three-phase flow. As such, a multiphase flow meter may be used to determine an amount of oil or a portion of oil within a multiphase flow that travels through a wellhead during a given period of time. A multiphase flow meter may also include hardware that uses various types of sensors based on different sensing technologies (e.g., nuclear magnetic resonance, electromagnetic sensors, acoustic sensors, etc.) and interpretation models. For example, a multiphase flow meter may use a sensor response of magnetic resonance information to determine the number of hydrogen atoms in a particular fluid flow. Since oil, gas, and water each contain hydrogen atoms, properties of a multiphase flow may be measured using magnetic resonance. The hydrogen atoms in a magnetized fluid may respond to radio frequency pulses and emit echoes that are subsequently recorded and analyzed by the multiphase flow meter. Thus, multiphase flow rate measurements may be used for production monitoring, well control, and/or reservoir optimization.

Moreover, a multiphase flow metering system may include a multiphase flow meter and a host device. In response to determining flow rate data regarding a multiphase flow, a multiphase flow meter may transmit flow rate data to a host device, such as a well control system or another type of computer system, over a network. The multiphase flow meter may be coupled to one or more flow tubes in order to determine the flow rate data, such as individual flow rates and/or oil, gas, and/or water fractions of a corresponding multiphase flow. A flow tube may be a fluid conduit, such as pipe, that may provide a fluid sampling for analysis by the multiphase flow meter. Examples of flow tubes may include a bent flow tube, a straight flow tube, or another type of flow tube. Furthermore, a flow model may be stored within a multiphase flow meter as a portion of a database and/or as one or more flow regime maps that are associated with various sensor values. By analyzing sensor data in connection with one or more flow models, a flow meter may determine flow rate data that corresponds to acquired sensor data. Flow rate data may include corresponding fractional data (e.g., gas fraction of a multiphase flow) and/or velocity data (e.g., an individual flow rate of oil or water in the multiphase flow).

Furthermore, the multiphase flow meter may include a flow meter controller that controls sensing operations and/or the flow analysis operations. In some embodiments, a flow controller uses one or more flow models to determine flow rate data regarding a particular flow. Phase distribution information may describe the respective fractions of one or more phases (e.g., gas phase, oil phase, water phase), in a particular flow. Flow regime information may refer to a specific manner that two or three phases flow through a flow tube. For example, a flow regime may be expressed using various superficial velocities. One example of a flow regime may be a “bubble regime,” in which gas is entrained as bubbles within a liquid. Another example of a flow regime is a “slug regime” that may correspond to a series of liquid “slugs” or “plugs” separated by relatively large gas pockets. Accordingly, a flow model may describe changes in a multiphase flow between transitions from high-liquid compositions to high-gas compositions and vice versa. Other flow regimes may include an annular flow regime, a dispersed flow regime, and a froth flow regime.

In some embodiments, one or more production logging tools (PLT) are used to determine production data at one or more depth intervals in a production well. For example, PLT data at a particular depth may include wellbore temperature measurements, pressure measurements, fluid density measurements, flow velocity measurements, and holdup data (e.g., volume fraction of a pipe occupied by fluid). While measurements of pressure, temperature and flow rate can be obtained at the surface, surface measurements may not necessarily reflect what is happening in the reservoir. As such, PLT data may be acquired downhole using various logging tools. More specifically, fluid velocity data may be acquired using a spinner flowmeter. In particular, a spinner flowmeter may include a rotating blade that turns when fluid moves past the device (e.g., the rotational speed of the blade in revolutions per second (RPS) may be proportional to the fluid velocity). Moreover, PLT data may be acquired using a production logging toolstring. This toolstring may include a fullbore spinner, various fluid holdup and bubble count probes, a pipe diameter caliper tool, a bearing sensor, a pressure sensor, a temperature sensor, a gamma ray tool, a casing collar locator, one or more batteries, and/or a data recorder. Other production logging tools include markers/tracers such as oxygen activation logs or radioactive iodine tracer logs as well as anemometers. An anemometer may be an instrument that measures the speed or velocity of gases in a contained flow. As such, PLT operations may include temperature logging, radioactive tracer logging, noise logging, focused gamma ray density logging, unfocused gamma ray density logging, fluid capacitance logging, fluid identification logging in high angle wells, and flowmeter logging at different depth intervals.

Keeping with production logging tools, various types of logging tools may be used to provide information during production operations and afterwards. For example, production logging may determine an axial flow rate based on axial velocity data and an internal diameter of a pipe component. Likewise, production logging may be used to track movement of fluid either inside or immediately outside the casing of a wellbore. Examples of production logs include temperature surveys, mechanical flowmeter surveys, and borehole fluid-density surveys, and fluid-capacitance surveys. Moreover, PLT data may be used to determine whether a production problem exists, such as excessive water or gas production. In particular, PLT data may be used to determine whether a production problem is the result of a completion problem or a reservoir problem. In some embodiments, production logging is used to determine the location of casing damage or collars. Likewise, PLT data may also determine water holdup in a wellbore or a well's gas volume fraction. Thus, PLT data may provide detailed, multiphase evaluation of fluid velocity and phase identification in vertical, deviated, and horizontal wells. More specifically, PLT data may identify fluid entry, gas leaks, injection zones, and cement tops through various well or reservoir analyses.

In some embodiments, the well system (106) includes a water cut sensor. For example, a water cut sensor may be hardware and/or software with functionality for determining the water content in oil, also referred to as “water cut.” Measurements from a water cut sensor may be referred to as water cut data and may describe the ratio of water produced from the wellbore (120) compared to the total volume of liquids produced from the wellbore (120). Water cut sensors may implement various water cut measuring techniques, such as those based on capacitance measurements, Coriolis effect, infrared (IR) spectroscopy, gamma ray spectroscopy, and microwave technology. Water cut data may be obtained during production operations to determine various fluid rates found in production from the well system (106).

With regard to microwave-based water cut sensors, certain microwave-based water cut sensors may rely on measuring a phase difference between transmitted and received microwave signals. As such, the phase difference may have a direct link with the effective permittivity of the oil and water mixture from the wellbore (120). In some embodiments, microwave-based water cut sensors employ transmit (Tx) antennas and receive (Rx) antennas disposed inside of well system pipe, such that the antennas are at least partially immersed in the fluid mixture as the fluid flows through the pipe.

In some embodiments, the well system (106) includes a water cut sensing system that includes a water cut (WC) sensor, a cylindrical pipe, and/or a measurement processing system. The WC sensor may be disposed on (or otherwise integrated within) the cylindrical pipe. As such, the WC sensor may include a signal conductor (SC) (e.g., a first conductive plane), such as a T-resonator, disposed at a first/upper/top surface of the cylindrical pipe, and a ground conductor (GC) (e.g., a second conductive plane) disposed at a second/lower/bottom surface of the cylindrical pipe that is opposite the first/upper/top surface of the pipe. In such a configuration, the WC sensing system may be employed to sense a water cut of fluid obtained from the wellbore (120) (e.g., a water and oil mixture, or other substrate). In some embodiments, a WC sensor includes multiple waveguides that are attached to a production pipe, where a network analyzer may be connected to the waveguides. The network analyzer may be communicatively coupled with the well control system (126) to determine water cut data.

In some embodiments, production wells and/or injection wells are involved in one or more stimulation operations. For example, one type of stimulation operation is a water-alternating-gas (WAG) operation. A WAG operation may be a cyclic process of injecting water followed by gas. Using a WAG injection, macroscopic or microscopic sweep efficiency may be improved for a reservoir, e.g., by maintaining nearly initial high pressure, slow down any gas breakthroughs, and reduce oil viscosity. Likewise, WAG injections may also decrease residual oil saturation resulting from three phase flows and effects associated with relative permeability hysteresis. Thus, some stimulation operations may produce gas flooding, which is a type of enhanced oil recovery (EOR) method for increasing recovery of light to moderate oil reservoirs. In some stimulation operations, water may be injected during the initial phase of the operation and followed by a gas (e.g., carbon dioxide) because water may have a higher mobility ratio than the injected gas, thereby preventing breakthroughs in the reservoir. Injected gas may be a mixture of hydrocarbon gas or nonhydrocarbon gases. With hydrocarbon gases, the gas mixture may include methane, ethane, and propane for achieving a miscible or immiscible gas-oil system in the reservoir. With nonhydrocarbon gases, the gas mixture may include carbon dioxide (CO₂), nitrogen (N₂), and some exotic gases that displace fluid in the reservoir. Likewise, gas may also be injected directly into a reservoir, e.g., into the gas cap, to compensate for the reservoir's pressure decline.

Furthermore, a stimulation injection during a stimulation operation may correspond to various injection parameters, such as bank size, cycle time, and a predetermined water-gas ratio (also called a “WAG ratio”). Bank size may refer to a size of sequential banks of fluids (e.g., oil, CO₂ and water) formed in the reservoir rock in response to a stimulation operation that migrate from the injection to the production wells. For illustration, a WAG ratio of 1:1 may result in a high oil production for one or more production wells, such as production wells coupled to a miscible reservoir. Based on some reservoir parameters such as oil composition, gas flooding can be carried out in miscible or immiscible conditions. Moreover, different types of stimulation operations may use different stimulation parameters. Examples of different stimulation operations may include: (1) continuous gas injections; (2) WAG injections; (3) simultaneous water-alternating-gas (SWAG) injections; and (4) tapered WAG injections. Different strategies have been developed by the petroleum industry to cope with these conditions.

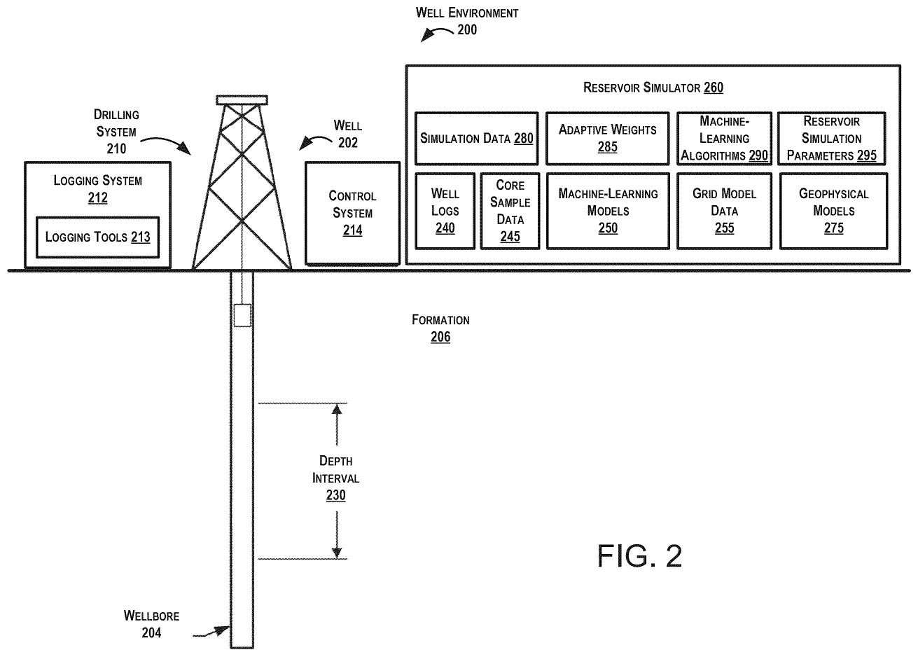

Turning to FIG. 2, FIG. 2 shows a schematic diagram in accordance with one or more embodiments. As shown, FIG. 2 illustrates a well environment (200) that may include a well (202) having a wellbore (204) extending into a formation (206). The wellbore (204) may include a bored hole that extends from the surface into a target zone of the formation (206), such as a reservoir. The formation (206) may include various formation characteristics of interest, such as formation porosity, formation permeability, resistivity, density, water saturation, and the like. Porosity may indicate how much space exists in a particular rock within an area of interest in the formation (206), where oil, gas, and/or water may be trapped. Permeability may indicate the ability of liquids and gases to flow through the rock within the area of interest. Resistivity may indicate how strongly rock and/or fluid within the formation (206) opposes the flow of electrical current. For example, resistivity may be indicative of the porosity of the formation (206) and the presence of hydrocarbons. More specifically, resistivity may be relatively low for a formation that has high porosity and a large amount of water, and resistivity may be relatively high for a formation that has low porosity or includes a large amount of hydrocarbons. Water saturation may indicate the fraction of water in a given pore space.

Keeping with FIG. 2, the well environment (200) may include reservoir simulator (260) and various well systems, such as a drilling system (210), a logging system (212), and a control system (214). The drilling system (210) may include a drill string, drill bit, a mud circulation system and/or the like for use in boring the wellbore (204) into the formation (206). Well systems may also include production systems that include production trees, production valves, downhole sensors, wellhead sensors, and the like. The control system (214) may include hardware and/or software for managing drilling operations or production operations. For example, the control system (214) may include one or more programmable logic controllers (PLCs) that include hardware and/or software with functionality to control one or more processes performed by the drilling system (210). A logging system may be similar to a control system with a specific focus on managing one or more logging tools.

Turning to the reservoir simulator (260), a reservoir simulator (260) may include hardware and/or software with functionality for performing one or more reservoir simulations (e.g., to produce simulation data (280) based on reservoir simulation parameters (285)). Likewise, a reservoir simulator may store and analyze well logs (240), core sample data (245), PLT data, surface production data, cutting data, acoustic sensing data, seismic data, and/or other types of geophysical data to generate and/or update one or more geophysical models (275) and/or machine-learning models (250). Geophysical models may include geochemical or geomechanical models that describe structural relationships and/or geophysical properties (e.g., porosity, permeability, electrical resistivity, a particle velocity of medium, etc.) within a particular geological region. Likewise, a geophysical model may identify one or more rock types associated with one or more geological regions (e.g., formation (206)). Examples of rock types may include one or more depositional rock types (e.g., where a geological region is based on a depositional environment), rock types that include similar diagenetic processes, rock types based on similar geological trends, and/or rock types based on similar reservoir properties. For example, a rock type may correspond to an irreducible water saturation, residual oil saturations, rock permeability, capillary pressure, maximum capillary pressure heights, relative permeabilities, and rock classes.

The logging system (212) may include one or more logging tools (213) for use in generating well logs of the formation (206). For example, a logging tool may be lowered into the wellbore (204) to acquire measurements as the tool traverses a depth interval (230) (e.g., a targeted reservoir section) of the wellbore (204). The plot of the logging measurements versus depth may be referred to as a “log” or “well log”. Well logs (240) may provide depth measurements of the well (204) that describe such reservoir characteristics as formation porosity, formation permeability, resistivity, water saturation, and the like. The resulting logging measurements may be stored and/or processed, for example, by the control system (214), to generate corresponding well logs for the well (202). A well log (240) may include, for example, a plot of a logging response time versus true vertical depth (TVD) across the depth interval (230) of the wellbore (204).

Turning to examples of logging techniques, multiple types of logging techniques are available for determining various reservoir characteristics (e.g., wireline logging, logging-while-drilling (LWD), and measurement-while-drilling (MWD)). In some embodiments, gamma ray logging is used to measure naturally occurring gamma radiation to characterize rock or sediment regions within a wellbore. In particular, different types of rock may emit different amounts and different spectra of natural gamma radiation. For example, gamma ray logs may distinguish between shales and sandstones/carbonate rocks because radioactive potassium may be common to shales. Likewise, the cation exchange capacity of clay within shales may also result in higher absorption of uranium and thorium further increasing the amount of gamma radiation produced by shales.

Turning to nuclear magnetic resonance (NMR) logging, an NMR logging tool may measure the induced magnetic moment of hydrogen nuclei (i.e., protons) contained within the fluid-filled pore space of porous media (e.g., reservoir rocks). Thus, NMR logs may measure the magnetic response of fluids present in the pore spaces of the reservoir rocks. In so doing, NMR logs may measure both porosity and permeability, as well as the types of fluids present in the pore spaces. Thus, NMR logging may be a subcategory of electromagnetic logging that responds to the presence of hydrogen protons rather than a rock matrix. Because hydrogen protons may occur primarily in pore fluids, NMR logging may directly or indirectly measure the volume, composition, viscosity, and distribution of pore fluids.

Turning to spontaneous potential (SP) logging, SP logging may determine the permeabilities of rocks in the formation (206) by measuring the amount of electrical current generated between drilling fluid produced by the drilling system (210) and formation water that is held in pore spaces of the reservoir rock. Porous sandstones with high permeabilities may generate more electricity than impermeable shales. Thus, SP logs may be used to identify sandstones from shales.

Another type of electrical logging technique is resistivity logging. Resistivity logging may measure the electrical resistivity of rock or sediment in and around the wellbore (204). In particular, resistivity measurements may determine what types of fluids are present in the formation (206) by measuring how effective these rocks are at conducting electricity. Because fresh water and oil are poor conductors of electricity, they have high resistivities. As such, resistivity measurements obtained via such logging can be used to determine corresponding reservoir water saturation (S_{w}).

Another electrical logging technique is dielectric logging. For example, dielectric permittivity may be defined as a physical quantity that describes the propagation of an electromagnetic field through a dielectric medium. As such, dielectric permittivity may describe a physical medium's ability to polarize in response to an electromagnetic field, and thus reduce the total electric field inside the physical medium. In a portion of reservoir rock, water may have a large dielectric permittivity that is higher than any associated rock or hydrocarbon fluids within the portion. In particular, water permittivity may depend on a frequency of an electromagnetic wave, water pressure, water temperature, and salinity of the reservoir rock mixture. Likewise, a multi-frequency dielectric logging tool may determine a value of the water-filled porosity in the reservoir rock.

Keeping with dielectric logging, a dielectric logging tool may determine a dielectric constant (i.e., relative-permittivity) measurement. For example, the dielectric logging tool may include an antenna that detects relative dielectric constants between different fluids at a fluid interface. As such, a dielectric logging tool may generate a dielectric log of the high-frequency dielectric properties of a formation. In particular, a dielectric log may include two curves, where one curve may describe the relative dielectric permittivity of the analyzed rock and the other curve may describe the resistivity of the analyzed rock. Relative dielectric permittivity may be used to distinguish hydrocarbons from water of differing salinities. However, the effect of salinity may be more important than the salinity effect with a high-frequency dielectric log (also called an “electromagnetic propagation log”).

Turning to sonic logging or acoustic logging, the logging system (212) may measure the speed that acoustic waves travel through rocks in the formation (206) to determine porosity in the formation (206). This type of logging may generate borehole compensated (BHC) logs, which are also called sonic logs. In general, sound waves may travel faster through high-density shales than through lower-density sandstones. Other types of logging include density logging and neutron logging. Density logging may determine porosity measurements by directly measuring the density of the rocks in the formation (206). Furthermore, neutron logging may determine porosity measurements by assuming that the reservoir pore spaces within the formation (206) are filled with either water or oil and then measuring the amount of hydrogen atoms (i.e., neutrons) in the pores.

Turning to coring, reservoir characteristics may be determined using core sample data (e.g., core sample data (245)) acquired from a well site. For example, certain reservoir characteristics can be determined via a coring system (e.g., physical extraction of rock specimens) to produce core specimens and/or logging operations (e.g., wireline logging, logging-while-drilling (LWD) and measurement-while-drilling (MWD)). Coring operations may include physically extracting a rock specimen from a region of interest within the wellbore (204) for detailed laboratory analysis. For example, when drilling an oil or gas well, a coring system may include coring bit that cuts core plugs (or “cores” or “core specimens”) from the formation (206) and bring the core plugs to the surface, and these core specimens may be analyzed at the surface (e.g., in a lab) to determine various characteristics of the formation (206) at the location where the specimen was obtained.

Turning to various coring technique examples, conventional coring may include collecting a cylindrical specimen of rock from the wellbore (204) using a core bit, a core barrel, and a core catcher. The core bit may have a hole in its center that allows the core bit to drill around a central cylinder of rock. Subsequently, the resulting core specimen may be acquired by the core bit and disposed inside the core barrel. More specifically, the core barrel may include a special storage chamber within a coring tool for holding the core specimen. Furthermore, the core catcher may provide a grip to the bottom of a core and, as tension is applied to the drill string, the rock under the core breaks away from the undrilled formation below a coring tool. Thus, the core catcher may retain the core specimen to avoid the core specimen falling through the bottom of the drill string. In some embodiments, a micro computed tomography (micro-CT) scan is performed on a core sample. Several types of micro-CT scanning may be used, such as a desktop micro-CT scanner that uses an X-ray generation tube, and a synchrotron X-ray micro-tomography. In particular, a micro-CT scanner may use various X-rays to penetrate from different viewpoints in a core sample to produce an attenuated projection profile that is used for later reconstruction using a filtered back projection algorithm.

In some embodiments, cutting samples are acquired and analyzed from one or more drilling operations to determine various geological properties of one or more formations. In particular, cuttings may be initially cleaned in liquid detergent to remove drilling additives and before being dried on a ‘hotplate’. Dried cutting samples may be passed through one or more sieves to remove fragments of various sizes. Likewise, a magnet may be placed over a sieved cutting sample to remove any metallic fragments acquired during a drilling operation. After selecting various desired samples from the sieving and other preparation processes, selected samples may be ground into a fine powder for analysis using X-ray fluorescence (XRF) spectrometry processing and/or and inductively coupled plasma (ICP) spectrometry processing.

Turning to geosteering, geosteering may be used to position the drill bit or drill string of the drilling system (210) relative to a boundary between different subsurface layers (e.g., overlying, underlying, and lateral layers of a pay zone) during drilling operations. In particular, measuring rock properties during drilling may provide the drilling system (210) with the ability to steer the drill bit in the direction of desired hydrocarbon concentrations. As such, a geosteering system may use various sensors located inside or adjacent to the drill string to determine different rock formations within a well path. In some geosteering systems, drilling tools may use resistivity or acoustic measurements to guide the drill bit during horizontal or lateral drilling. Likewise, a well path of a wellbore (204) may be updated by the control system (214) using a geophysical model (e.g., one of the geophysical models (275)). For example, a control system (214) may communicate geosteering commands to the drilling system (210) based on well data updates that are further adjusted by the reservoir simulator (260) using a geophysical model. As such, the control system (214) may generate one or more control signals for drilling equipment (or a logging system may generate for logging equipment) based on an updated well path design and/or a geophysical model.

Keeping with FIG. 2, a reservoir simulator (e.g., reservoir simulator (260)) may include hardware and/or software with functionality for generating and/or updating one or more machine-learning models (e.g., machine-learning models (250)) to determine predicted simulation data and/or adaptive weights (e.g., adaptive weights (285)) for determining predicting simulation data. Examples of machine-learning models may include random forest models and artificial neural networks, such as convolutional neural networks, fully-connected neural networks, deep neural networks, and recurrent neural networks. Machine-learning models may also include support vector machines, decision trees, inductive learning models, deductive learning models, supervised learning models, unsupervised learning models, reinforcement learning models, and the like. In a deep neural network, for example, a layer of neurons may be trained on a predetermined list of features based on the previous network layer's output. Thus, as data progresses through the deep neural network, more complex features may be identified within the data by neurons in later layers. In some embodiments, two or more different types of machine-learning models are integrated into a single machine-learning architecture, e.g., a machine-learning model may include a random forest model and various neural networks. In some embodiments, a reservoir simulator may generate augmented data or synthetic data to produce a large amount of interpreted data for training a particular model.

In some embodiments, various types of machine-learning algorithms (e.g., machine-learning algorithms (290)) may be used to train the model, such as a backpropagation algorithm. In a backpropagation algorithm, gradients are computed for each hidden layer of a neural network in reverse from the layer closest to the output layer proceeding to the layer closest to the input layer. As such, a gradient may be calculated using the transpose of the weights of a respective hidden layer based on an error function (also called a “loss function”). The error function may be based on various criteria, such as mean squared error function, a similarity function, etc., where the error function may be used as a feedback mechanism for tuning weights in the machine-learning model.

In some embodiments, a machine-learning model is trained using multiple epochs. For example, an epoch may be an iteration of a model through a portion or all of a training dataset. As such, a single machine-learning epoch may correspond to a specific batch of training data, where the training data is divided into multiple batches for multiple epochs. Thus, a machine-learning model may be trained iteratively using epochs until the model achieves a predetermined criterion, such as predetermined level of prediction accuracy or training over a specific number of machine-learning epochs or iterations. Thus, better training of a model may lead to better predictions by a trained model.

With respect to artificial neural networks, for example, an artificial neural network may include one or more hidden layers, where a hidden layer includes one or more neurons. A neuron may be a modelling node or object that is loosely patterned on a neuron of the human brain. In particular, a neuron may combine data inputs with a set of coefficients, i.e., a set of network weights for adjusting the data inputs. These network weights may amplify or reduce the value of a particular data input, thereby assigning an amount of significance to various data inputs for a task being modeled. Through machine learning, a neural network may determine which data inputs should receive greater priority in determining one or more specified outputs of the artificial neural network. Likewise, these weighted data inputs may be summed such that this sum is communicated through a neuron's activation function to other hidden layers within the artificial neural network. As such, the activation function may determine whether and to what extent an output of a neuron progresses to other neurons where the output may be weighted again for use as an input to the next hidden layer.

Turning to fully-connected neural networks, a fully connected neural network may include a series of fully connected layers (e.g., an input layer, one or more hidden layers, and an output layer) that connect each neuron in one layer to every neuron in the next layer. As such, fully-connected neural networks may be referred to as “structurally agnostic” in that there are no special assumptions needed to be made about the input data, such whether the input is an image, a continuous range of values, and/or categorized inputs.

Turning to convolution neural networks, a convolution neural network may obtain images as input data, which may allow encoding certain properties into the network's model architecture. For example, a convolution neural network may include a sequence of hidden layers, where a hidden layer may transform one volume of activations to another set of activations through a differentiable function. Examples of specific hidden layers in a convolution neural network include convolutional layers, pooling layers, fully-connected layers, and/or normalization layers. Likewise, a U-net model or other type of convolutional neural network model may use these different types of layers to produce a particular type of output.

Turning to recurrent neural networks, a recurrent neural network (RNN) may perform a particular task repeatedly for multiple data elements in an input sequence (e.g., a sequence of temperature values or flow rate values), with the output of the recurrent neural network being dependent on past computations. As such, a recurrent neural network may operate with a memory or hidden cell state, which provides information for use by the current cell computation with respect to the current data input. For example, a recurrent neural network may resemble a chain-like structure of RNN cells, where different types of recurrent neural networks may have different types of repeating RNN cells. Likewise, the input sequence may be time-series data, where hidden cell states may have different values at different time steps during a prediction or training operation. For example, where a deep neural network may use different parameters at each hidden layer, a recurrent neural network may have common parameters in an RNN cell, which may be performed across multiple time steps. To train a recurrent neural network, a supervised learning algorithm such as a backpropagation algorithm may also be used. In some embodiments, the backpropagation algorithm is a backpropagation through time (BPTT) algorithm. Likewise, a BPTT algorithm may determine gradients to update various hidden layers and neurons within a recurrent neural network in a similar manner as used to train various deep neural networks.

Embodiments are contemplated with different types of RNNs. For example, classic RNNs, long short-term memory (LSTM) networks, a gated recurrent unit (GRU), a stacked LSTM that includes multiple hidden LSTM layers (i.e., each LSTM layer includes multiple RNN cells), recurrent neural networks with attention (i.e., the machine-learning model may focus attention on specific elements in an input sequence), bidirectional recurrent neural networks (e.g., a machine-learning model that may be trained in both time directions simultaneously, with separate hidden layers, such as forward layers and backward layers), as well as multidimensional LSTM networks, graph recurrent neural networks, grid recurrent neural networks, etc. With regard to LSTM networks, an LSTM cell may include various output lines that carry vectors of information, e.g., from the output of one LSTM cell to the input of another LSTM cell. Thus, an LSTM cell may include multiple hidden layers as well as various pointwise operation units that perform computations such as vector addition.

In some embodiments, a reservoir simulator uses one or more ensemble learning methods to produce a hybrid-model architecture. For example, an ensemble learning method may use multiple types of machine-learning models to obtain better predictive performance than available with a single machine-learning model. In some embodiments, for example, an ensemble architecture may combine multiple base models to produce a single machine-learning model. One example of an ensemble learning method is a BAGGing model (i.e., BAGGing refers to a model that performs Bootstrapping and Aggregation operations) that combines predictions from multiple neural networks to add a bias that reduces variance of a single trained neural network model. Another ensemble learning method includes a stacking method, which may involve fitting many different model types on the same data and using another machine-learning model to combine various predictions.

Turning to random forests, a random forest model may an algorithmic model that combines the output of multiple decision trees to reach a single predicted result. For example, a random forest model may be composed of a collection of decision trees, where training the random forest model may be based on three main hyperparameters that include node size, a number of decision trees, and a number of input features being sampled. During training, a random forest model may allow different decision trees to randomly sample from a dataset with replacement (e.g., from a bootstrap sample) to produce multiple final decision trees in the trained model. For example, when multiple decision trees form an ensemble in the random forest model, this ensemble may determine more accurate predicted data, particularly when the individual trees are uncorrelated with each other. In some embodiments, a random forest model implements a software algorithm that is an extension of a bagging method. As, a random forest model may use both bagging and feature randomness to create an uncorrelated forest of decision trees. Feature randomness (also referred to as “feature bagging”) may generate a random subset of input features. This random subject may thereby result in low correlation among decision trees in the random forest model. In a training operation for a random forest model, a training operation may search for decision trees that provide the best split to subset particular data, such as through a Classification and Regression Tree (CART) algorithm. Different metrics, such as information gain or mean square error (MSE), may be used to determine the quality of a data split for various decision trees.

Keeping with random forests, a random forest model may be a classifier that uses data having discrete labels or classes. Likewise, a random forest model may also be used as a random forest regressor to solve regression problems. Depending on the type of problem being addressed by the random forest model, how predicted data is determined may vary accordingly. For a regression task, the individual decision trees may be averaged in a predicted result. For a classification task, a majority vote (e.g., predicting an output based on the most frequent categorical variable) may determine a predicted class. In a random forest regressor, the model may work with data having a numeric or continuous output, which cannot be defined by distinct classes.

Turning to reinforcement learning, a reservoir simulator may perform one or more reinforcement learning algorithms using a reinforcement learning system to train a machine-learning model. In particular, a reinforcement learning algorithm may be a type of method that autonomously learns agent policies through multiple iterations of trials and evaluations based on observation data. The objective of a reinforcement learning algorithm may be to learn an agent policy π that maps one or more states of an environment to an action so as to maximize an expected reward J(π). A value reward may describe one or more qualities of particular state, agent action, and/or trajectory at particular time within an operation, such as an electric power generation operation. As such, a reinforcement learning system may include hardware and/or software with functionality for implementing one or more reinforcement learning algorithms. For example, a reinforcement learning algorithm may train a policy to make a sequence of decisions based on the observed states of the environment to maximize the cumulative reward determined by a reward function. For example, a reinforcement learning algorithm may employ a trial-and-error procedure to determine one or more agent policies based on various agent interactions with a complex environment, such as a reservoir simulation environment with multiple production wells and injection wells. As such, a reinforcement learning algorithm may include a reward function that teaches a particular action selection engine to follow certain rules, while still allowing the reinforcement learning model to retain information learned from previous reservoir simulations.

In some embodiments, one or more components in a reinforcement learning system are trained using a training system. For example, an agent policy and/or a reward function may be updated through a training process that is performed by a machine-learning algorithm. In some embodiments, historical data, augmented data, and/or synthetic data may provide a supervised signal for training an action selector engine, an agent policy, and/or a reward function, such as through an imitation learning algorithm. In another embodiment, an interactive expert may provide data for adjusting agent policies and/or reward functions.

Turning to deep reinforcement learning, deep reinforcement learning may combine various machine-learning models (e.g., artificial neural networks) with a framework of reinforcement learning that helps agents learn how to reach their goals. That is, deep reinforcement learning may use both function approximation and target optimization in order to map various states and actions to specific rewards. For example, artificial neural networks as used in computer vision, natural language processing, and time series predictions may be combined with reinforcement learning algorithms.

While the reservoir simulator (260) is shown at a well site in FIG. 2, in some embodiments, the reservoir simulator (260) or other components in FIG. 2 may be remote from a well site. In some embodiments, the reservoir simulator (260) is implemented as part of a software platform for the control system (214) in FIG. 2. The software platform may obtain data acquired by the drilling system (210) and the logging system (212) as inputs, which may include multiple data types from multiple sources. The software platform may aggregate the data from these systems (210, 212, 214) in real time for rapid analysis. In some embodiments, the control system (214), the logging system (212), the reservoir simulator (260), and/or a user device coupled to one of these systems may include a computer system that is similar to the computer system (802) described below with regard to FIG. 8 and the accompanying description.

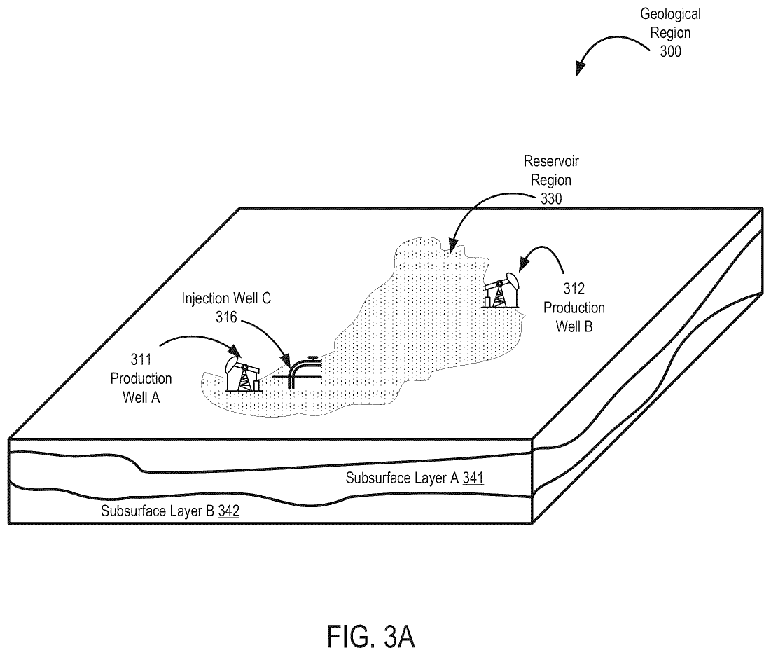

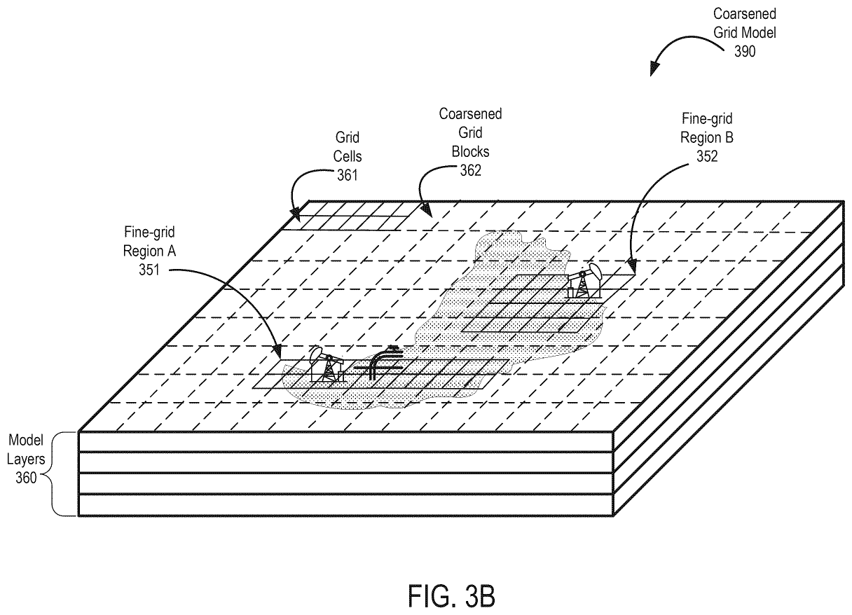

Turning to FIG. 3A, FIG. 3A shows a schematic diagram in accordance with one or more embodiments. As illustrated in FIG. 3A, FIG. 3A shows a geological region (300) that may include one or more reservoir regions (e.g., reservoir region (330)) with various production wells (e.g., production well A (311), production well (312)). For example, a production well may be similar to the well system (106) described above in FIG. 1 and the accompanying description. Likewise, a reservoir region may also include one or more injection wells (e.g., injection well C (316)) that include functionality for enhancing production by one or more neighboring production wells. As shown in FIG. 3A, wells may be disposed in the reservoir region (330) above various subsurface layers (e.g., subsurface layer A (341), subsurface layer B (342)), which may include hydrocarbon deposits. In particular, production data and/or injection data may exist for a particular well, where production data may include data that describes production or production operations at a well, such as wellhead data (140) described in FIG. 1 and the accompanying description.

Turning to FIG. 3B, FIG. 3B shows a schematic diagram in accordance with one or more embodiments. As illustrated in FIG. 3B, FIG. 3B shows a coarsened grid model (390) that corresponds to the geological region (300) from FIG. 3A. More specifically, the coarsened grid model (390) includes grid cells (361) that may refer to an original cell of a grid model as well as coarsened grid blocks (362) that may refer to an amalgamation of original cells of the grid model. For example, a grid cell may be the case of a 1×1 block, where coarsened grid blocks may be of sizes 2×2, 4×4, 8×8, etc. Both the grid cells (361) and the coarsened grid blocks (362) may correspond to columns for multiple model layers (360) within the coarsened grid model (390).

Prior to performing a reservoir simulation, local grid refinement and coarsening (LGR) may be used to increase or decrease grid resolutions in various regions of a grid model. For example, various reservoir properties, e.g., permeability, porosity, or saturations, may correspond to discrete values that are associated with a particular grid cell or coarsened grid block. However, by using discrete values to represent a portion of a geological region, a discretization error may occur in a reservoir simulation. Thus, various fine-grid regions may reduce discretization errors as the numerical approximation of a finer grid is closer to the exact solution, however through a higher computational cost. As shown in FIG. 3B, for example, the coarsened grid model (390) may include various fine-grid regions (i.e., fine-grid region A (351), fine-grid region B (352)), that are surrounded by coarsened block regions. Likewise, the original grid model without any coarsening may be referred to as a fine-grid model.

In general, coarsening may be applied to cells that do not contribute to a total flow within a reservoir region because a slight change on such reservoir properties may not affect the output of a simulation. Accordingly, different levels of coarsening may be used on different regions of the same reservoir model. As such, a coarsening ratio may correspond to a measure of coarsening efficiency, which may be defined as a total number of cells in a coarsened reservoir model divided by the original number of cells in the original reservoir model.

In some embodiments, one or more coarsening functions are used to produce a coarsened-grid model. In particular, a coarsening function may be based on one or more fluid characterizations (e.g., to produce a proxy model with less rigorous fluid characterization), streamlines, or any other criterion that may provide a satisfactory estimate of future reservoir performance within a geological region. In order to reduce computational time, a coarsened grid model may be generated by coarsening cells that do not contribute to a total flow of a reservoir region, because a slight change on reservoir properties, i.e., permeability, porosity or fluid saturations, may impact reservoir simulations. Accordingly, a coarsening function may be based on various flow properties of a reservoir region of interest.

While FIGS. 1, 2, 3A, and 3B show various configurations of components, other configurations may be used without departing from the scope of the disclosure. For example, various components in FIGS. 1, 2, 3A, and 3B may be combined to create a single component. As another example, the functionality performed by a single component may be performed by two or more components.

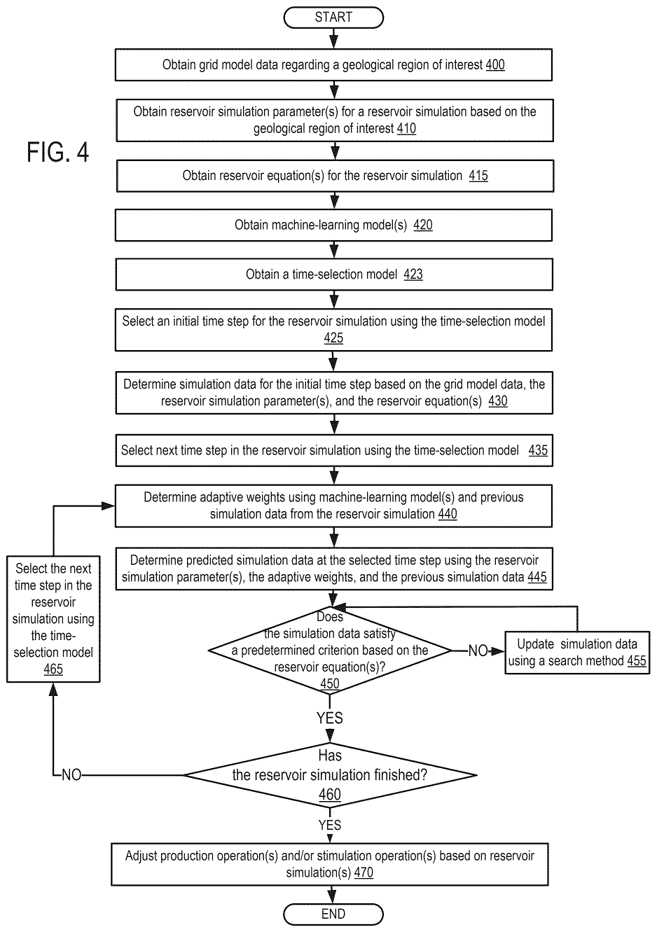

Turning to FIG. 4, FIG. 4 shows a flowchart in accordance with one or more embodiments. Specifically, FIG. 4 describes a general method for simulating a geological region of interest using predicted simulation data and machine learning. One or more blocks in FIG. 4 may be performed by one or more components (e.g., reservoir simulator (160)) as described in FIGS. 1, 2, 3A, and 3B. While the various blocks in FIG. 4 are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

In Block 400, grid model data are obtained regarding a geological region of interest in accordance with one or more embodiments. For example, a reservoir simulator may access model data from a fine-grid model, where the grid model data includes various reservoir property values, such as oil saturation, water saturation, and gas saturation. Grid model data may also refer to data that remains approximately constant throughout a reservoir simulation, such as rock porosity, formation lithology, and/or rock matrix permeability of various cells in a grid model. A geological region of interest may be a portion of a geological area or volume that includes one or more wells or formations of interest desired or selected for further analysis, e.g., for determining a location of hydrocarbons or reservoir development purposes for a respective reservoir. As such, a geological region of interest may include one or more reservoir regions selected for running simulations. For example, the geological region of interest may be similar to geological region (300) or reservoir region (330) described above in FIG. 3A and the accompanying description.

In Block 410, one or more reservoir simulation parameters are obtained for a reservoir simulation based on a geological region of interest in accordance with one or more embodiments. For example, reservoir simulation parameters may describe well parameters of one or more production wells and/or one or more injection wells in a reservoir simulation. In particular, reservoir simulation parameters may correspond to wellhead data described above in FIG. 1 as well as various well design parameters, e.g., type of wellbore, such as a vertical or horizontal well, and/or specific wellbore dimensions. Reservoir simulation parameters may also include historical production data or historical injection data, such as flow rate data, surface pressure data, etc., or simulated well data from one or more previous reservoir simulations. Reservoir simulation parameters may also include predicted well data or adjusted well data obtained during a reservoir simulation. For example, a reservoir simulation may attempt to optimize production data for multiple wells in an oil field over a predetermined time period.

In Block 415, one or more reservoir equations are obtained for a reservoir simulation in accordance with one or more embodiments. For example, reservoir equations may include one or more flow equations that describe various flow properties within one or more regions of a geological region of interest. Examples of reservoir equations include Darcy's equations, incompressible and compressible fluid flow equations, material-balance equations, constraint rate equations, black-oil equations, and the like. More specifically, reservoir equations may be nonlinear equations that may be solved at a particular time step using one or more nonlinear solvers.

In some embodiments, linear solver and nonlinear solvers include hardware and/or software that perform mathematical operations in order to determine a solution to a predetermined mathematical problem. For example, a solver may be arbitrarily nested (i.e., as a “nested solver”) within a simulation workflow that determines individual property values of one or more linear equations (e.g., values within a single grid or multiple grids) or one or more nonlinear equations.

With respect to nonlinear equations, a nonlinear solver may determine a solution to a nonlinear system, in which a change of an output is not proportional to a change of an input to the nonlinear system. As such, a nonlinear solver may be an iterative solver that implements a repeating algorithmic procedure that includes one or more predetermined termination criteria (e.g., when a particular criterion is satisfied based on an updated value, the iterative method may terminate). Likewise, an iterative solver may use a search method, such as a Newton-Raphson method (also called “Newton's method”), a secant method, or a bisection method, to determine a solution to a particular problem or equation. For example, a Newton-Raphson method may include a root-finding algorithm that produces successively better approximations to the roots of a real-valued function. A secant method may include a root-finding algorithm that uses a succession of roots of secant lines to better approximate a root of a real-valued function. A bisection method (also called a “binary search method”) may include a root-finding algorithm applicable to various continuous functions that has two known values with opposite signs. The bisection method may repeatedly bisect an interval defined by these known values and then select a subinterval in which a continuous function changes signs (i.e., that contains a root).

In Block 420, one or more machine-learning models are obtained in accordance with one or more embodiments. In some embodiments, a machine-learning model is trained using various partial differential equation (PDE) solutions, such as from a PDE solution database. A training dataset for a machine-learning model may include various reservoir simulation models with randomly sampled reservoir simulation properties (e.g., petrophysical properties), bottomhole pressures for various wells, and wellhead data (e.g., wellhead temperatures, flow rates, etc.). Moreover, a machine-learning model may also be trained on past reservoir simulations for the same geological region and/or other reservoir simulations for other reservoir regions. In some embodiments, a machine-learning model is trained to predict simulation data at different time steps in a reservoir simulation using a reinforcement learning algorithm. For example, a machine-learning model may learn actively as a reservoir simulation progresses to provide more accurate initial simulation data prior to using any linear and/or nonlinear solvers. Thus, the initial starting point for future timesteps of the same reservoir simulation may be improved throughout simulation process.

In Block 423, a time-selection model is obtained in accordance with one or more embodiments. For example, a time-selection model may be based on a constant step size for subsequent time steps in a reservoir simulation. However, a time-selection model may also be based on adaptive selection, where the size of a time step changes based on simulation data and/or reservoir boundary conditions. In particular, an adaptive selection model may be used in a reservoir simulation when a large variation is determined for one or more derivatives of one or more reservoir equations.

Turning to adaptive selection models, an adaptive selection model may be based on one or more simulation parameters, such as pressure changes in a reservoir simulation. Additionally, the adaptive selection model may also use one or more past time step sizes to determine the next time step size. For example, a maximal pressure drop in a particular time step may be compared to a preset hyperparameter dPₘₐₓ. For illustration, an example of an adaptive selection model is shown in the following equation:

$$Δ {t}_{i} = \frac{{dP}_{max}}{{‖ {P}_{i} - {P}_{i - 1} ‖}_{L 1}} Δ {t}_{i - 1} \qquad Equation 1$$

where Pᵢ corresponds to simulated pressure data at a current time step, Pᵢ₋₁ corresponds to simulated pressure data at the previous time step, Δtᵢ corresponds to an adaptive change in a time step size, and Δtᵢ₋₁ corresponds to an adaptive change in a previous time step size. In Equation 1 above, the L1 norm (i.e., the maximal absolute value among various pressure changes in the grid space) may be measured over a flattened vector, and index I refers to the current state of the reservoir simulation. As such, the adaptive selection model in Equation 1 may determine at each time step of a reservoir simulation, a change in time step size Δt based on a resulting pressure drop close to a value of dPₘₐₓ.

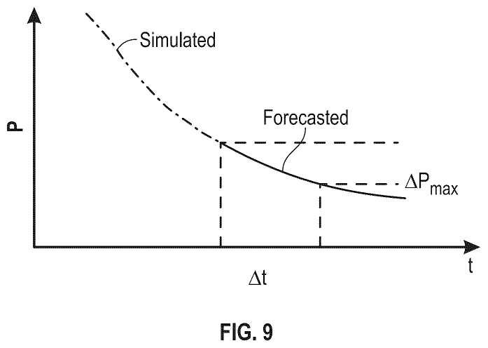

Turning to FIG. 9, FIG. 9 illustrates an example of an adaptive selection scheme based on changes in pressure over time in a reservoir simulation. As shown in FIG. 9, the slope of a mean pressure drop may become flatter over time during a reservoir simulation, which may result a timestep size that becomes closer to dPₘₐₓ in later time periods in the reservoir simulation.

In some embodiments, a time-selection model is a machine-learning selection model. More specifically, a machine-learning selection model may use determine predicted time step sizes for one or more time steps in the future within a reservoir simulation. Rather than simply relying on current and previous time step sizes as well as past simulation data, a machine-learning selection model may use a machine-learning solver to determine a predicted size of future time steps. The machine-learning selection model may use as inputs previous simulation data, grid model data, and/or reservoir simulation parameters. An example of a machine-learning model solver may be a machine-learning model similar to one or more of the machine-learning models described above in FIG. 2 and the accompanying description.

Keeping with machine-learning selection models, a machine-learning selection model may include a machine-learning model that determines predicted sizes for a predetermined number of future time steps (e.g., an artificial neural network may determine six future time step sizes based on input pressure data from a reservoir simulation). While an adaptive selection model may rely on the current and the previous steps, a machine-learning selection model may be trained to predict an optimum time step size using data regarding the current reservoir simulation as well as data from other reservoir simulations using the same or different grid models. In some embodiments, for example, a machine-learning selection model is expressed using the following equations:

$${j}^{*} = max \{ j ∈ \{ 1 , 2 , … , k \} : \frac{{‖ {P}_{i + j} - {P}_{i} ‖}_{L 1}}{{dP}_{max}} \leq 1 \} \qquad Equation 2$$

$$Δ {t}_{i} = \frac{{dP}_{max}}{{P}_{i + j *} - {P}_{i}} ( {t}_{i + j *} - {t}_{i} ) \qquad Equation 3$$

As shown above in Equations 2 and 3, a machine-learning adaptive step strategy may be performed based on a current pressure Pᵢ at time instant tᵢ and for a predetermined number of future time steps k and predicted pressure states Pᵢ₊₁, . . . , Pᵢ₊ₖ at time instants tᵢ₊₁, . . . , tᵢ₊ₖ. More specifically, the differences ∥Pᵢ₊ⱼ−Pᵢ∥_{L1} for j=1, . . . , k may be used to determine a max number of time steps j, which provides the closest difference to dPₘₐₓ. As such, the predicted Δtᵢ in Equation 3 may provide the best approximation of the time instant, at which expected pressure drop reaches the limiting value dPₘₐₓ. Thus, this predicted Δtᵢ may also be the input parameter in a Newton-Raphson method.

In Block 425, an initial time step is selected for a reservoir simulation using a time-selection model in accordance with one or more embodiments. For example, a user may choose one or more time selections within a graphical user interface for a reservoir simulation with a grid model for a particular geological region. A time selection may specify the starting time, the ending time, and/or a duration time of the reservoir simulation. In some embodiments, a time selection specifies a particular time step interval that may be computed based on other user input parameters (e.g., as a percentage of a time selection of an entire reservoir simulation). In some embodiments, a reservoir simulator automatically determines a respective time step based on analyzing reservoir simulation parameters, such as the desired runtime or the desired ending time.

In Block 430, simulation data are determined for an initial time step based on grid model data, one or more reservoir simulation parameters, and one or more reservoir equations in accordance with one or more embodiments. In particular, simulation data for an initial time step may correspond to a starting approximation of the geological region that may be equal to one or more boundary conditions.

In Block 435, a next time step is selected in a reservoir simulation using a time-selection model in accordance with one or more embodiments. For example, a reservoir simulator may iterate to the next time step based on the time selection for a reservoir simulation.

In Block 440, various adaptive weights are determined using one or more machine-learning models and previous simulation data from a reservoir simulation in accordance with one or more embodiments. Adaptive weights may be used to determine a weighted sum of previous simulation data in a regression algorithm. The weighted sum may provide the predicted simulation data in Block 445 below for use in determining a reservoir solution of the current time step. In some embodiments, different samples of simulation data are assigned different weights for determining the initial prediction at a particular time step. In particular, adaptive weights may be determined as an output to one or more machine-learning models, such as a fully-connected neural network or a convolution neural network. Based on the values assigned adaptive weights, different simulation data may be reweighted throughout the reservoir simulation. The machine-learning models may be similar to one or more machine-learning models described above in FIG. 2 and the accompanying description.

Furthermore, previous simulation data may be preprocessed prior to being used as inputs to a machine-learning model. For example, a mathematical function, such as a mean function or a median function, may be applied to simulation data. Thus, an average simulation value (e.g., an average bottomhole or an average flowrate) may be used as inputs to the machine-learning model.

In some embodiments, adaptive weights may correspond to an adaptive weight map that identifies specific solution values in a grid model for predicting simulation accordingly. The adaptive weight map may also identify various cells in the predicted simulation data that will correspond to the final simulation data in a previous time step.

In Block 445, predicted simulation data are determined at a selected time step using one or more reservoir simulation parameters, various adaptive weights, and previous simulation data in accordance with one or more embodiments.

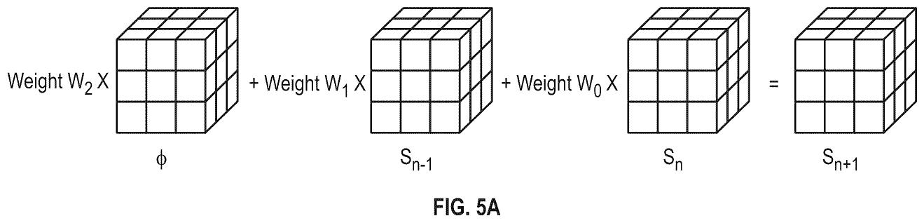

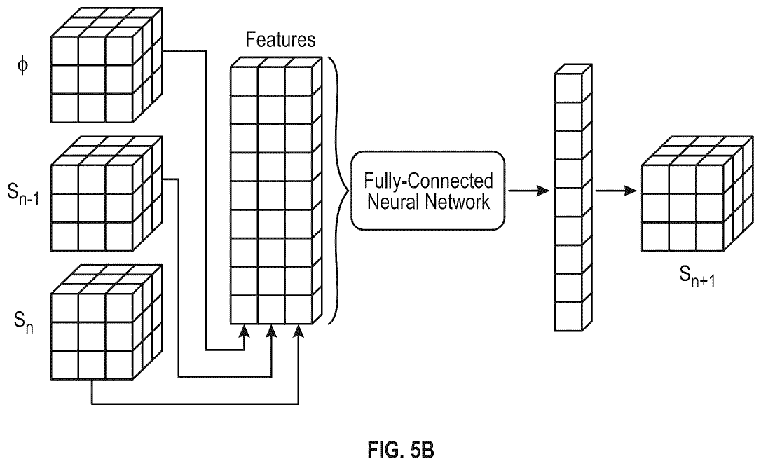

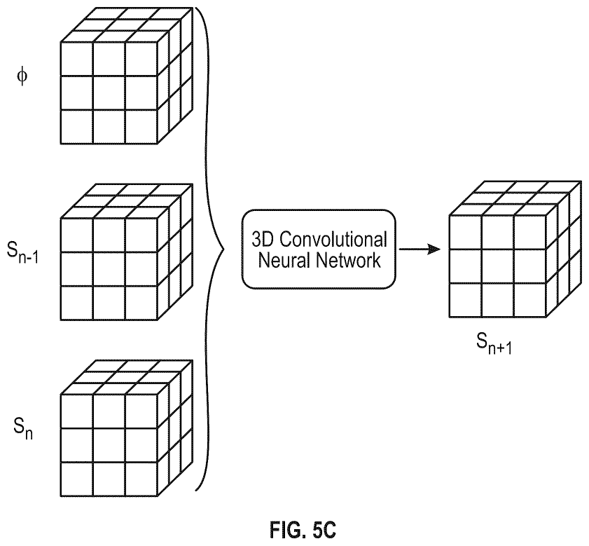

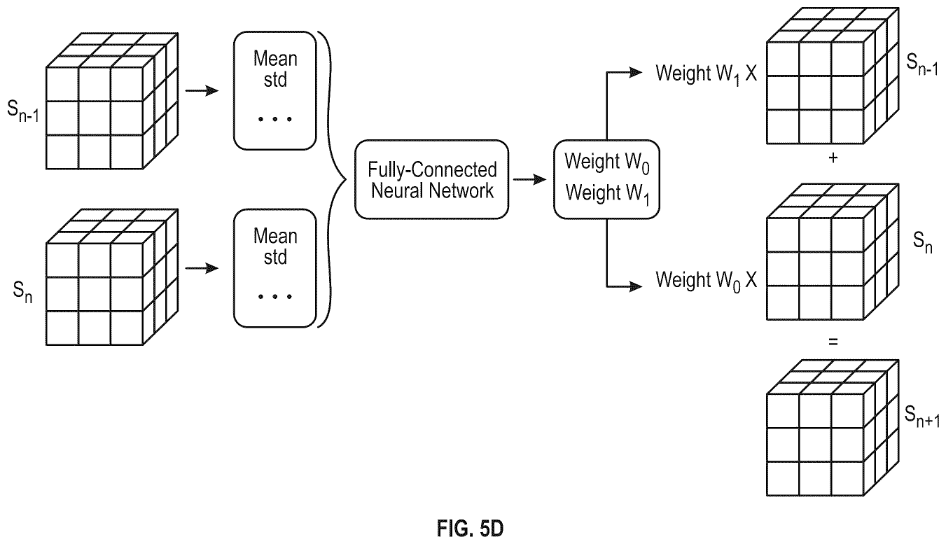

Turning to FIGS. 5A-5D, FIGS. 5A, 5B, 5C, 5D show various machine-learning architectures for determining predicted simulation data in accordance with one or more embodiments. FIG. 5A shows an example of a linear regression model that includes trainable weights. For example, trainable weights may be trained by a supervised learning algorithm based on a training data. On the other hand, FIG. 5B shows an example of a fully connected artificial neural network (ANN) that determines predicted simulation data directly without adaptive weights. Additionally, FIG. 5C shows an example of a convolutional ANN that determines predicted simulation data. Finally, FIG. 5D shows an example of a regression model with adaptive weights for determining predicted simulation data.

Keeping with FIGS. 5A-5D, simulation data sₙ may refer to the current time step of a reservoir simulation with the corresponding reservoir properties and model data. Previous simulation data may be referred to using the states sₙ₋ₖ, sₙ₋ₖ₊₁, . . . , sₙ₋₁, where k defines the prehistory length of the respective reservoir simulation. Moreover, Δi may refer to the difference between the simulation state sₙ₋ᵢ and sₙ₋ᵢ₋₁, i.e., Δᵢ=sₙ₋ᵢ₋₁−sₙ₋ᵢ for i=0, . . . , k−1. In one approach for predicting simulation data, a linear combination of sₙ₋ₖ, . . . , sₙ is used to predict the next state sₙ₊₁, i.e., as shown in the linear regression model illustrated in FIG. 5A. This predicted simulation data may be used as the initial reservoir solution in a Newton-Raphson method. Another approach for determining predicted simulation data may use a linear combination of the differences Δₖ₋₁, . . . , Δ₀ to predict the next difference Δ₋₁=sₙ−sₙ₊₁. In this case, we use sₙ+Δ₋₁ as the initial approximation of the reservoir solution at the next time step.

In some embodiments, a reservoir simulator uses grid model data (e.g., porosity and permeability values for various cells), reservoir simulation parameters (e.g., starting time step and final time step), and previous simulation data to determine predicted simulation data with a machine-learning model. As such, the machine-learning model may determine predicted simulation data that provides an initial solution to various reservoir equations for the current time step. Likewise, some initial simulation data may be determined using adaptive weights, while other initial simulation data may be predicted without adaptive weights.

In Block 450, a determination is made whether simulation data satisfies a predetermined criterion based on one or more reservoir equations in accordance with one or more embodiments. For example, a reservoir simulator may analyze simulation data at a particular time step for whether the simulation data satisfies a predetermined criterion. Predetermined criteria may include convergence criteria, such as whether the predicted simulation data and/or the simulation data produced from a search method has converged to a global minimum. Likewise, the predetermined criterion may be a specified number of searching iterations. If the simulation data satisfied the predetermined criterion, the process may proceed to Block 460. If the simulation data does not satisfy the predetermined criterion, the process may proceed to Block 455.

In Block 455, simulation data is updated using a search method in accordance with one or more embodiments. Various search methods may be used for solving nonlinear systems representative of a geological region, such as the Newton-Raphson method or secant method. A Newton-Raphson method may be based on approximating a nonlinear function by Tailor's decomposition rule. The linear part of the decomposition may be used to define the root of the nonlinear function. As the Newton-Raphson method is iterative, convergence speed of a reservoir solution may depend on the selection of the initial simulation data for a particular time step. Moreover, initial simulation data may be predicted simulation data from one or more machine-learning models or the simulation data from the previous iteration of the Newton-Raphson method.

In Block 460, a determination is made whether a reservoir simulation has finished in accordance with one or more embodiments. For example, a reservoir simulation may end once the simulation achieves a certain milestone or reaches a specific time step. If another time step remains in a time selection for the reservoir simulation, the process may proceed to Block 465. If no more time steps remain in the reservoir simulation, the process may proceed to Block 470.

In Block 465, a next time step is selected for a reservoir simulation using a time-selection model in accordance with one or more embodiments.

In Block 470, one or more production operations and/or stimulation operations are adjusted based on one or more reservoir simulations in accordance with one or more embodiments.

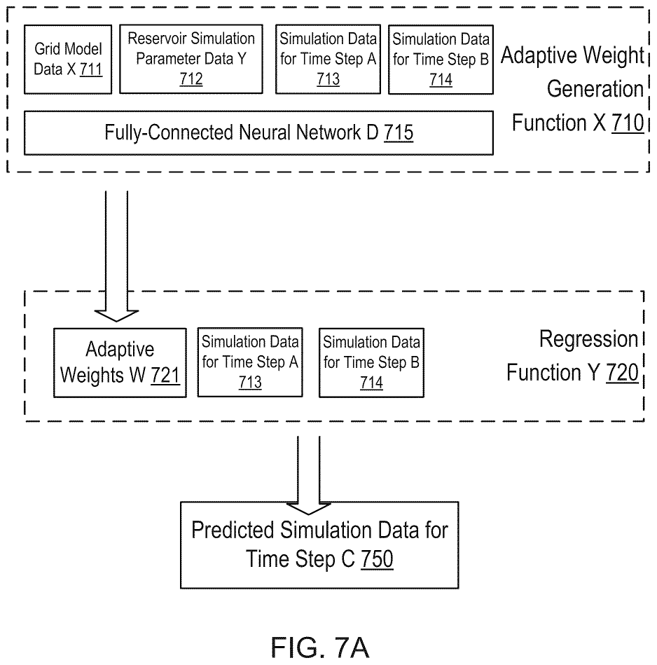

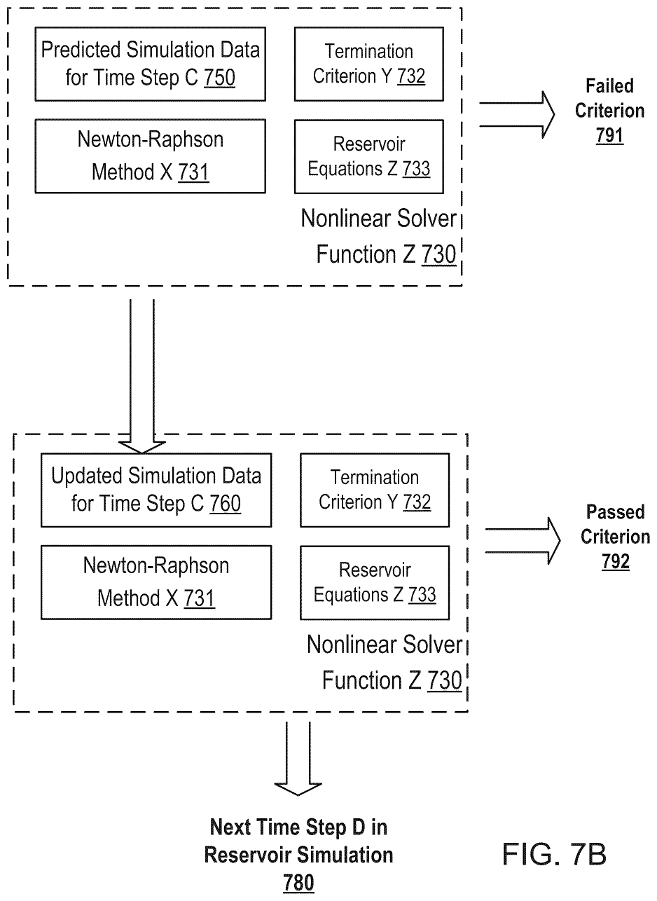

Turning to FIGS. 7A-7B, FIGS. 7A-7B provides an example of using multiple adaptive weights and machine learning in a reservoir simulation in accordance with one or more embodiments. The following example is for explanatory purposes only and not intended to limit the scope of the disclosed technology. As shown in FIG. 7A, a reservoir simulator (not shown) obtains grid model data X (711), reservoir simulation parameter data Y (712), simulation data (713) for time step A, and simulation data (714) for time step B. For the current time step C, the reservoir simulator applies an adaptive weight generation function X (710) to the grid model data X (711), reservoir simulation parameter data Y (712), and simulation data (713, 714) using a fully-connected neural network D (715). The data (711, 712, 713, 714) provides inputs to the fully-connected neural network D (715), and the fully-connected neural network D (715) outputs adaptive weights W (721). Afterwards, the reservoir simulator applies a regression function Y (720) to the simulation data (713, 714) based on the adaptive weights W (721) to generate predicted simulation data (750) for time step C.

Turning to FIG. 7B, the reservoir simulator uses the predicted simulation data (750) in a nonlinear solver function Z (730) for determining a reservoir solution at current time step C. In particular, the reservoir simulator analyzes the predicted simulation data (750) using reservoir equations Z (733) in view of a particular predetermined criterion, i.e., termination criterion Y (732) that species a predetermined data misfit between the simulation data and the reservoir equations Z (733). Using the nonlinear solver function Z (730), the reservoir simulator determines that the predicted simulation data (750) fails to satisfy the termination criterion Y (732) and outputs a determination of a failed criterion (791). The reservoir simulator then updates the predicted simulation data (750) using a Newton-Raphson method X (731) to produce updated simulation data (760) for time step C. The reservoir simulator again analyses the updated simulation data (750) based on the termination criterion Y (732) and outputs a determination of a passed criterion (792). As such, the updated simulation data becomes the final simulation data for time step C, and the reservoir simulator proceeds to the next time step D (780) in the running reservoir simulation.

Embodiments may be implemented on a computer system. FIG. 8 is a block diagram of a computer system (802) used to provide computational functionalities associated with described algorithms, methods, functions, processes, flows, and procedures as described in the instant disclosure, according to an implementation. The illustrated computer (802) is intended to encompass any computing device such as a high performance computing (HPC) device, server, desktop computer, laptop/notebook computer, wireless data port, smart phone, personal data assistant (PDA), tablet computing device, one or more computer processors within these devices, or any other suitable processing device, including both physical or virtual instances (or both) of the computing device. Additionally, the computer (802) may include a computer that includes an input device, such as a keypad, keyboard, touch screen, or other device that can accept user information, and an output device that conveys information associated with the operation of the computer (802), including digital data, visual, or audio information (or a combination of information), or a GUI.

The computer (802) can serve in a role as a client, network component, a server, a database or other persistency, or any other component (or a combination of roles) of a computer system for performing the subject matter described in the instant disclosure. The illustrated computer (802) is communicably coupled with a network (830). In some implementations, one or more components of the computer (802) may be configured to operate within environments, including cloud-computing-based, local, global, or other environment (or a combination of environments).

At a high level, the computer (802) is an electronic computing device operable to receive, transmit, process, store, or manage data and information associated with the described subject matter. According to some implementations, the computer (802) may also include or be communicably coupled with an application server, e-mail server, web server, caching server, streaming data server, business intelligence (BI) server, or other server (or a combination of servers).

The computer (802) can receive requests over network (830) from a client application (for example, executing on another computer (802)) and responding to the received requests by processing the said requests in an appropriate software application. In addition, requests may also be sent to the computer (802) from internal users (for example, from a command console or by other appropriate access method), external or third-parties, other automated applications, as well as any other appropriate entities, individuals, systems, or computers.

Each of the components of the computer (802) can communicate using a system bus (803). In some implementations, any or all of the components of the computer (802), both hardware or software (or a combination of hardware and software), may interface with each other or the interface (804) (or a combination of both) over the system bus (803) using an application programming interface (API) (812) or a service layer (813) (or a combination of the API (812) and service layer (813). The API (812) may include specifications for routines, data structures, and object classes. The API (812) may be either computer-language independent or dependent and refer to a complete interface, a single function, or even a set of APIs. The service layer (813) provides software services to the computer (802) or other components (whether or not illustrated) that are communicably coupled to the computer (802). The functionality of the computer (802) may be accessible for all service consumers using this service layer. Software services, such as those provided by the service layer (813), provide reusable, defined business functionalities through a defined interface. For example, the interface may be software written in JAVA, C++, or other suitable language providing data in extensible markup language (XML) format or other suitable format. While illustrated as an integrated component of the computer (802), alternative implementations may illustrate the API (812) or the service layer (813) as stand-alone components in relation to other components of the computer (802) or other components (whether or not illustrated) that are communicably coupled to the computer (802). Moreover, any or all parts of the API (812) or the service layer (813) may be implemented as child or sub-modules of another software module, enterprise application, or hardware module without departing from the scope of this disclosure.

The computer (802) includes an interface (804). Although illustrated as a single interface (804) in FIG. 8, two or more interfaces (804) may be used according to particular needs, desires, or particular implementations of the computer (802). The interface (804) is used by the computer (802) for communicating with other systems in a distributed environment that are connected to the network (830). Generally, the interface (804 includes logic encoded in software or hardware (or a combination of software and hardware) and operable to communicate with the network (830). More specifically, the interface (804) may include software supporting one or more communication protocols associated with communications such that the network (830) or interface's hardware is operable to communicate physical signals within and outside of the illustrated computer (802).

The computer (802) includes at least one computer processor (805). Although illustrated as a single processor (805) in FIG. 8, two or more computer processors may be used according to particular needs, desires, or particular implementations of the computer (802). Generally, the computer processor (805) executes instructions and manipulates data to perform the operations of the computer (802) and any algorithms, methods, functions, processes, flows, and procedures as described in the instant disclosure.

The computer (802) also includes a memory (806) that holds data for the computer (802) or other components (or a combination of both) that can be connected to the network (830). For example, memory (806) can be a database storing data consistent with this disclosure. Although illustrated as a single memory (806) in FIG. 8, two or more memories may be used according to particular needs, desires, or particular implementations of the computer (802) and the described functionality. While memory (806) is illustrated as an integral component of the computer (802), in alternative implementations, memory (806) can be external to the computer (802).

The application (807) is an algorithmic software engine providing functionality according to particular needs, desires, or particular implementations of the computer (802), particularly with respect to functionality described in this disclosure. For example, application (807) can serve as one or more components, modules, applications, etc. Further, although illustrated as a single application (807), the application (807) may be implemented as multiple applications (807) on the computer (802). In addition, although illustrated as integral to the computer (802), in alternative implementations, the application (807) can be external to the computer (802).

There may be any number of computers (802) associated with, or external to, a computer system containing computer (802), each computer (802) communicating over network (830). Further, the term “client,” “user,” and other appropriate terminology may be used interchangeably as appropriate without departing from the scope of this disclosure. Moreover, this disclosure contemplates that many users may use one computer (802), or that one user may use multiple computers (802).

In some embodiments, the computer (802) is implemented as part of a cloud computing system. For example, a cloud computing system may include one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which may be performed using one or more Internet connections. More specifically, cloud computing system may operate according to one or more service models, such as infrastructure as a service (IaaS), platform as a service (PaaS), software as a service (SaaS), mobile “backend” as a service (MBaaS), serverless computing, and/or function as a service (FaaS).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. A method, comprising:
obtaining grid model data regarding a geological region of interest, wherein the grid model data comprises porosity data, lithological data, and permeability data;
obtaining a plurality of reservoir simulation parameters for a reservoir simulation of the geological region of interest, wherein the plurality of reservoir simulation parameters comprises well data regarding one or more wells in the geological region of interest;
obtaining a plurality of reservoir equations for the reservoir simulation;
determining, by a computer processor, first simulation data for a first time step of the reservoir simulation based on the grid model data, the plurality of reservoir simulation parameters, and the plurality of reservoir equations;
determining, by the computer processor, second simulation data for a second time step of the reservoir simulation based on the grid model data, the plurality of reservoir simulation parameters, and the plurality of reservoir equations;
determining, by the computer processor, a first plurality of adaptive weights using a first machine-learning model, the first simulation data, and the second simulation data;
determining, by the computer processor, first predicted simulation data for a third time step of the reservoir simulation using the first plurality of adaptive weights, the first simulation data, the second simulation data, the grid model data, and the plurality of reservoir simulation parameters,
wherein a respective adaptive weight among the first plurality of adaptive weights adjusts a contribution of respective simulation data for determining the first predicted simulation data;
determining, by the computer processor, whether the first predicted simulation data satisfies a predetermined criterion, wherein the predetermined criterion is a convergence criterion corresponding to a reservoir solution to the plurality of reservoir equations converging to a predetermined limit; and
determining, by the computer processor and in response to determining that the first predicted simulation data fails to satisfy the predetermined criterion, updated simulation data for the third time step of the reservoir simulation based on the first predicted simulation data, the grid model data, the plurality of reservoir simulation parameters, a search method, and the plurality of reservoir equations.

2. The method of claim 1, further comprising:
obtaining a machine-learning selection model comprising a second machine-learning model that is different from the first machine-learning model;
determining third simulation data for a plurality of time steps in the reservoir simulation;
determining, using the machine-learning selection model and the third simulation data, a predicted time step size for a plurality of future time steps in the reservoir simulation; and
determining fourth simulation data for the plurality of future time steps using the predicted time step size, the grid model data, and the plurality of reservoir simulation parameters.

3. The method of claim 1, further comprising:
determining an agent policy for the reservoir simulation based on the geological region of interest, wherein the agent policy determines the first plurality of adaptive weights;
updating the agent policy to produce an updated agent policy using a reinforcement learning algorithm and fifth simulation data for a fourth time step;
determining a second plurality of adaptive weights based on the updated agent policy; and
determining second predicted simulation data for a fourth time step using the second plurality of adaptive weights.

4. The method of claim 1, further comprising:
obtaining a training dataset based on a plurality of reservoir simulations for a plurality of geological regions, wherein the training dataset comprises input simulation data for one or more time steps in a respective reservoir simulation and output simulation data for a predetermined time step for prediction in the respective reservoir simulation; and
training an initial model to produce the first machine-learning model using the training dataset and a plurality of machine-learning epochs.

5. The method of claim 1,
wherein the first machine-learning model is a fully-connected neural network that obtains the grid model data and the first simulation data for the first time step as input features to an input layer, and
wherein the fully-connected neural network outputs the first plurality of adaptive weights.

6. The method of claim 1,
wherein the search method is a Newton-Raphson method,
wherein the plurality of reservoir equations are selected from a group consisting of one or more Darcy's equations, one or more flow equations, one or more material-balance equations, and one or more constraint rate equations, and one or more black-oil equations, and
wherein the updated simulation data is determined using a nonlinear solver that determines a reservoir solution to the plurality of reservoir equations based on the Newton-Raphson method.

7. The method of claim 1,
wherein the plurality of reservoir simulation parameters comprise a first plurality of well parameters for one or more production wells and a second plurality of well parameters for one or more injection wells,
wherein the first plurality of well parameters comprise a predetermined rate of well production during the reservoir simulation, and
wherein the second plurality of well parameters describe one or more stimulation operations for the one or more injection wells.

8. The method of claim 1,
wherein the first predicted simulation data is based on a linear combination of the first simulation data and the second simulation data using a regression function and the first plurality of adaptive weights.

9. The method of claim 1, further comprising:
obtaining a time selection for the reservoir simulation,
wherein the time selection comprises a starting time, an ending time, and a predetermined time interval for a plurality of time steps in the reservoir simulation, and
wherein the reservoir simulation is an iterative process comprising the first time step, the second time step, and the third time step.

10. The method of claim 1, further comprising:
obtaining, using a logging system, a plurality of well logs from a well in the geological region of interest; and
determining the grid model data from the plurality of well logs.

11. The method of claim 1, further comprising:
obtaining, using a coring system, a plurality of core samples from a well in the geological region of interest; and
determining the grid model data from the plurality of core samples.

12. A system, comprising:
a plurality of wells in a geological region of interest;
a plurality of control systems coupled to the plurality of wells; and
a reservoir simulator comprising a computer processor, wherein the reservoir simulator is coupled to the plurality of control systems, the reservoir simulator being configured to perform a method comprising:
obtaining grid model data regarding a geological region of interest, wherein the grid model data comprises porosity data, lithological data, and permeability data;
obtaining a plurality of reservoir simulation parameters for a reservoir simulation of the geological region of interest, wherein the plurality of reservoir simulation parameters comprises well data regarding the plurality of wells;
obtaining a plurality of reservoir equations for the reservoir simulation;
determining first simulation data for a first time step of the reservoir simulation based on the grid model data, the plurality of reservoir simulation parameters, and the plurality of reservoir equations;
determining second simulation data for a second time step of the reservoir simulation based on the grid model data, the plurality of reservoir simulation parameters, and the plurality of reservoir equations;
determining a first plurality of adaptive weights using a first machine-learning model, the first simulation data, and the second simulation data;
determining first predicted simulation data for a third time step of the reservoir simulation using the first plurality of adaptive weights, the first simulation data, the second simulation data, the grid model data, and the plurality of reservoir simulation parameters,
wherein a respective adaptive weight among the first plurality of adaptive weights adjusts a contribution of respective simulation data for determining the first predicted simulation data;
determining whether the first predicted simulation data satisfies predetermined criterion, wherein the predetermined criterion is a convergence criterion corresponding to a reservoir solution to the plurality of reservoir equations converging to a predetermined limit; and
determining, in response to determining that the first predicted simulation data fails to satisfy the predetermined criterion, updated simulation data for the third time step of the reservoir simulation based on the first predicted simulation data, the grid model data, the plurality of reservoir simulation parameters, a search method, and the plurality of reservoir equations.

13. The system of claim 12, wherein the method further comprises:
obtaining a machine-learning selection model comprising a second machine-learning model that is different from the first machine-learning model;
determining third simulation data for a plurality of time steps in the reservoir simulation;
determining, using the machine-learning selection model and the third simulation data, a predicted time step size for a plurality of future time steps in the reservoir simulation; and
determining fourth simulation data for the plurality of future time steps using the predicted time step size, the grid model data, and the plurality of reservoir simulation parameters.

14. The system of claim 12, wherein the method further comprises:
determining an agent policy for the reservoir simulation based on the geological region of interest, wherein the agent policy determines the first plurality of adaptive weights;
updating the agent policy to produce an updated agent policy using a reinforcement learning algorithm and fifth simulation data for a fourth time step;
determining a second plurality of adaptive weights based on the updated agent policy; and
determining second predicted simulation data for a fourth time step using the second plurality of adaptive weights.

15. The system of claim 12, wherein the method further comprises:
obtaining a training dataset based on a plurality of reservoir simulations for a plurality of geological regions, wherein the training dataset comprises input simulation data for one or more time steps in a respective reservoir simulation and output simulation data for a predetermined time step for prediction in the respective reservoir simulation; and
training an initial model to produce the first machine-learning model using the training dataset and a plurality of machine-learning epochs.

16. The system of claim 12,
wherein the first machine-learning model is a fully-connected neural network that obtains the grid model data and the first simulation data for the first time step as input features to an input layer, and
wherein the fully-connected neural network outputs the first plurality of adaptive weights.

17. The system of claim 12,
wherein the search method is a Newton-Raphson method,
wherein the plurality of reservoir equations are selected from a group consisting of one or more Darcy's equations, one or more flow equations, one or more material-balance equations, and one or more constraint rate equations, and one or more black-oil equations, and
wherein the updated simulation data is determined using a nonlinear solver that determines a reservoir solution to the plurality of reservoir equations based on the Newton-Raphson method.

18. The system of claim 12,
wherein the plurality of reservoir simulation parameters comprise a first plurality of well parameters for one or more production wells and a second plurality of well parameters for one or more injection wells,
wherein the first plurality of well parameters comprise a predetermined rate of well production during the reservoir simulation, and
wherein the second plurality of well parameters describe one or more stimulation operations for the one or more injection wells.

19. The system of claim 12, further comprising:
a logging system coupled to a well in the geological region of interest,
wherein the logging system is configured to acquire a plurality of well logs from the well in the geological region of interest, and
wherein the grid model data is determined from the plurality of well logs.

20. The system of claim 12, further comprising:
a coring system coupled to a well in the geological region of interest,
wherein the coring system is configured to acquire a plurality of core samples from the well in the geological region of interest, and
wherein the grid model data is determined from the plurality of core samples.
